(19) United States
(12) Patent Application Publication
(10) Pub. No.: US 2025/0308982 A1
(43) Pub. Date: Oct. 2, 2025

(54) SELF-ALIGNED PATTERNED TRENCH ISOLATIONS FOR YIELD AND PERFORMANCE IMPROVEMENTS

(71) Applicant: Intel Corporation, Santa Clara, CA (US)

(72) Inventors: Yang Zhang, Rio Rancho, NM (US); Kan Zhang, Hillsboro, OR (US); Guowei Xu, Portland, OR (US); Tao Chu, Portland, OR (US); Robin Chao, Portland, OR (US); Feng Zhang, Portland, OR (US); Ting-Hsiang Hung, Beaverton, OR (US); Jianhua Yin, Portland, OR (US); Chia-Ching Lin, Portland, OR (US); Chun Wing Yeung, Portland, OR (US); Chung-Hsun Lin, Portland, OR (US); Anand Murthy, Portland, OR (US)

(73) Assignee: Intel Corporation, Santa Clara, CA (US)

(21) Appl. No.: 18/622,074

(22) Filed: Mar. 29, 2024

(51) Int. Cl. H01L 21/762; H01L 27/088; H01L 29/06; H01L 29/417; H01L 29/423; H01L 29/775; H01L 29/786

(52) U.S. Cl. CPC H01L 21/76224; H10D 30/43; H10D 30/6735; H10D 30/6757; H10D 62/121; H10D 64/251; H10D 84/83

(57) ABSTRACT

Integrated circuit (IC) device dielectrics in transistor trenches and trench isolations. An IC device may include adjacent source or drain bodies in a trench and in adjacent transistors, and at least three dielectrics in a stack between the source or drain bodies and between trench contacts on the source or drain bodies. A first dielectric in the stack is between the source or drain bodies and between the contacts, a second dielectric in the stack is on the first dielectric and between the contacts, and a third dielectric in the stack is on the second dielectric and between the contacts. A second trench with the three dielectrics may be adjacent to the first trench, and a trench isolation may be between the first and second trenches. The second dielectric may have an etch selectivity with the first dielectric in the stack and in the trench isolation.

### BACKGROUND

As transistors and other structures in integrated circuit (IC) devices are continuously scaled down, increasingly demanding tolerances are required, for example, in mask patterns, to support the fabrication of the scaled-down structures. Additional material (e.g., mask) layers or structures may also be used instead of, or to aid, patterned masks to protect retained materials and achieve properly aligned (e.g., etched) features. These added material layers or structures enable self-alignment of etches and subsequently deposited features. Improperly or insufficiently aligned etches (and subsequently depositions) may cause defects (and degrade yields, performance, reliability, etc.), for example, by removing materials where the materials are meant to be retained and/or inadvertently depositing materials in undesired locations.

New techniques, structures, and materials are needed to enable more-precise deposition and/or patterning requirements and so improve yields, performance, and reliability.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate cross-sectional profile views of an integrated circuit (IC) device having multiple dielectrics with etch selectivities adjacent transistor structures, in accordance with some embodiments;

FIGS. 2A, 2B, and 2C illustrate plan views of an IC device having a protective dielectric in dielectric stacks between adjacent metallization structures, in accordance with some embodiments;

FIGS. 3A and 3B illustrate cross-sectional profile views of an IC device having a trench isolation between source and drain bodies and metallization structures, and extending down through nanoribbon regions, in accordance with some embodiments;

FIG. 4 is a flow chart of methods for forming metallization structures adjacent a protective dielectric material that enables self-aligned isolations, in accordance with some embodiments;

FIGS. 5A, 5B, 5C, 5D, 5E and 5F illustrate cross-sectional profile views of transistor structures coupled to metallization structures adjacent dielectric stacks having a protective dielectric material, at various stages of manufacture, at various stages of manufacture, in accordance with some embodiments;

FIG. 6 illustrates a diagram of an example data server machine employing an IC device having dielectric stacks with a protective dielectric adjacent source and drain bodies and trench contacts, in accordance with some embodiments; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z and y-z planes are cross-sectional views. Where appropriate, drawings are labeled with axes to indicate the orientation of the figure.

Materials, structures, and techniques are disclosed to improve trench contacts and isolations in integrated circuit (IC) devices having trench isolations between nonplanar transistors.

Low-permittivity (“low-K”) dielectrics are extensively deployed throughout many IC devices. In some cases, an aggressive etch removing (including recessing) a common low-K dielectric can damage a similar dielectric nearby. For example, high-intensity dry etches for forming trench isolations may damage a low-K dielectric (and/or a liner dielectric over a low-K dielectric) in adjacent contact trenches. A same or similar low-K dielectric may then be deposited in the isolation trench before being recessed or completely removed from the isolation trench. An etch to recess or completely remove the low-K dielectric from the isolation trench may inadvertently damage or partially remove the adjacent low-K dielectric. A subsequently deposited dielectric liner may then unintentionally replace or cover the adjacent low-K dielectric. When the low-K dielectric in the adjacent contact trench is recessed to contact source or drain bodies in the contact trench, the unintentionally deposited dielectric liner may interfere with the dielectric recess and/or the contacting of the source or drain.

The employment of an additional, protective dielectric in the contact trench, over the low-K dielectric, may shield the low-K dielectric during isolation-trench etches. The protective dielectric may have an etch selectivity that allows the added dielectric to serve as a self-aligned mask to bracket or funnel the isolation-trench etches between the contact trenches. The protective dielectric may be retained or later removed, e.g., by planarization. The addition of the protective dielectric may improve trench contacts by preserving the low-K dielectric during isolation-trench etches and until the low-K dielectric is to be removed for trench contacting. The isolation etches may be improved by relaxed patterning constraints due to the self-aligned masking of the added, protective dielectric.

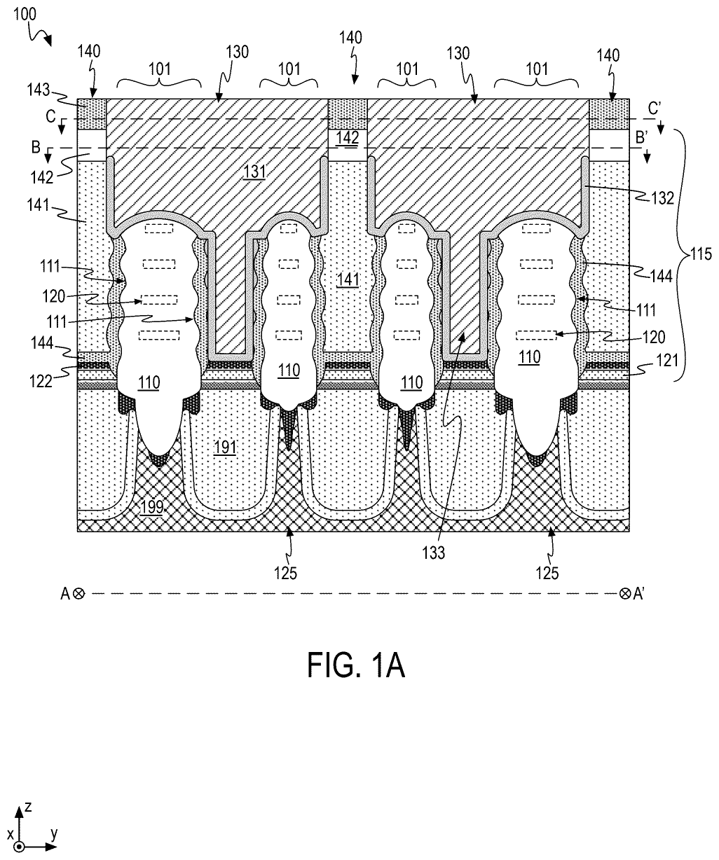

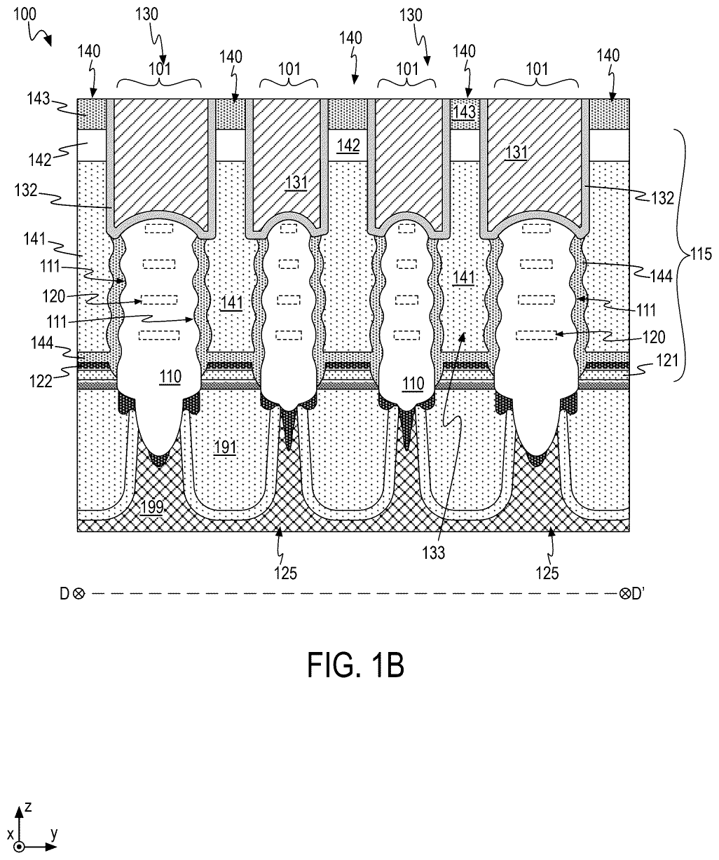

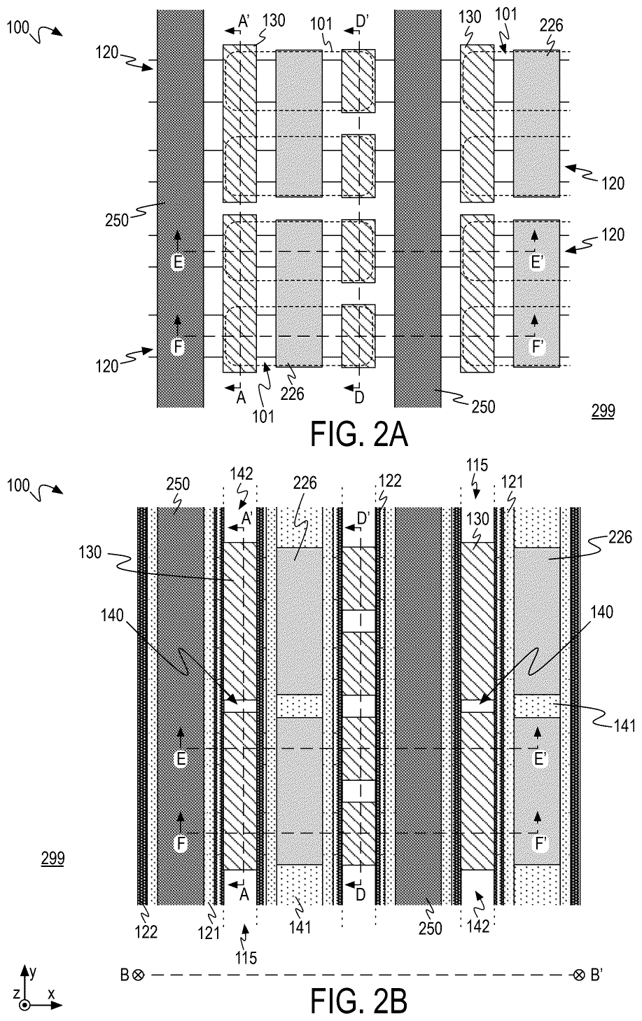

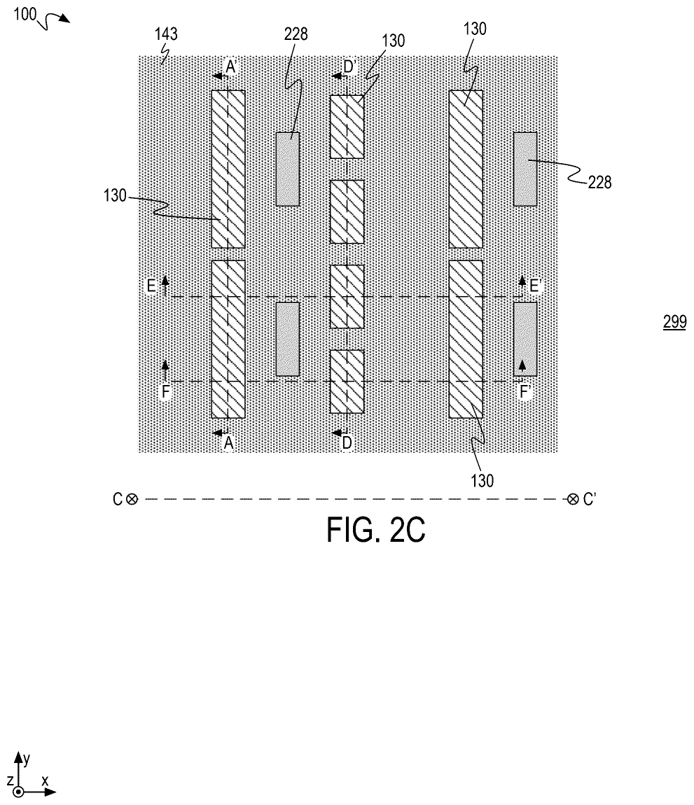

FIGS. 1A and 1B illustrate cross-sectional profile views of an IC device 100 having multiple dielectrics 141, 142, 143 with etch selectivities adjacent transistor structures 101, in accordance with some embodiments. For example, a durable dielectric 142 may be deployed over a low-K dielectric 141 and, due to an etch selectivity between dielectrics 141, 142, protect dielectric 141 during certain processing operations on device 100. FIG. 1A shows a cross-sectional profile view A-A′ of adjacent source and drain material bodies 110 over a substrate 199 and in transistor structures 101 and metallization structures 130 over and between bodies 110. The orientation and depth of plan views B-B′ of FIG. 2B and C-C′ of FIG. 2C are indicated in FIG. 1A (e.g., through dielectrics 142, 143, respectively). FIG. 1B illustrates a cross-sectional profile view D-D′ of dielectric stacks 140 between adjacent metallization structures 130 and between adjacent source and drain material bodies 110.

FIG. 1A shows a cross-sectional profile of IC device 100 in a y-z plane. Device 100 includes multiple transistor structures 101 having source and drain material bodies 110 in a trench 115 filled with dielectric 141. Each body 110 shown in FIG. 1A is in a distinct n- or p-type transistor structure 101. Complementary pairs of n- and p-type structures 101 are coupled (e.g., electrically) by shared structures 130 on the respective source or drain bodies 110 of each structure 101. For example, in the embodiment of FIG. 1A, the inner transistor structures 101 are p-type structures 101, and the outer structures 101 are n-type structures 101. Structures 101 may be metal-oxide semiconductor (MOS) structures 101. Pairs of n- and p-type transistor structures 101 may be in complementary devices, for example, complementary MOS (CMOS) devices. Other organizations (e.g., of all n- or all p-type structures 101) may be employed.

The cross-sectional profile view of FIG. 1A is through bodies 110 with channel regions 120 (shown with a dashed outline, though not actually in the viewing plane, e.g., for reference or illustrative purposes) in front of or behind the visible y-z plane. Transistor structures 101 each include pairs of bodies 110 coupled by channel regions 120. Source or drain material bodies 110 may be in contact with channel regions 120 in the positive and/or negative x-directions, in front of or behind the visible y-z plane. For example, each structure 101 may include a first source or drain body 110 in trench 115 and the y-z plane of FIG. 1A coupled by channel regions 120 to a second source or drain body 110 (not shown) in a second trench 115 (not shown) in the positive or negative x-direction. Each body 110 is coupled by one or more regions 120 in one or more pairs with one or more other bodies 110 in the positive and/or negative x-directions. For example, each visible body 110 may be paired by a channel region 120 to another body 110 (not shown in the viewing plane) in the positive x-direction, to another body 110 (not shown in the viewing plane) in the negative x-direction, or to bodies 110 in both the positive and negative x-directions.

Device 100 includes dielectric 141 over substrate 199 in a dielectric stack 140. Dielectric 141 is between adjacent bodies 110 and between adjacent metallization structures 130. Dielectric 142 is in stack 140, over dielectric 141 and between adjacent metallization structures 130. Dielectric 143 is in stack 140, over dielectric 142 and between adjacent metallization structures 130. Stacks 140 are to either side of structures 130, and each of the metallization structures 130 is between a pair of stacks 140. Dielectrics 141, 142, 143 are each distinct dielectric materials (e.g., a layer of dielectric 142 separates different dielectrics 141, 143, and is not just an etch-stop layer between two layers of dielectric 141 or 143 having a same composition).

Dielectrics 141, 142 are in trench 115, between and in contact with sidewalls (not shown) of trench 115. Dielectric 143 is over dielectrics 141, 142, but extends over and beyond sidewalls (not shown) of trench 115, e.g., in both the positive and negative x-directions. Trench 115 may be between (and formed by) adjacent gate structures over channel regions 120 coupled to source or drain bodies 110. Trenches 115 may extend in the y-directions, between parallel sidewalls of adjacent gate structures, the sidewalls also extending in the y-directions.

In many embodiments, dielectric 141 is a low-K dielectric, for example, having a relative permittivity or dielectric constant less than 5. In many embodiments, dielectric 141 has a lower relative permittivity or dielectric constant than dielectrics 142, 143. Dielectric 141 may provide isolation (e.g., electrical isolation) between adjacent structures in device 100, e.g., between adjacent source and drain bodies 110, between adjacent metallization structures 130, etc. In many embodiments, dielectric 141 includes oxygen. In some such embodiments, dielectric 141 includes silicon (e.g., in an oxide of silicon, SiₓO_{y}). Dielectric 141 may include other materials, e.g., additionally, to improve the characteristics of dielectric 141. Dielectric 141 may be of or include any suitable material(s).

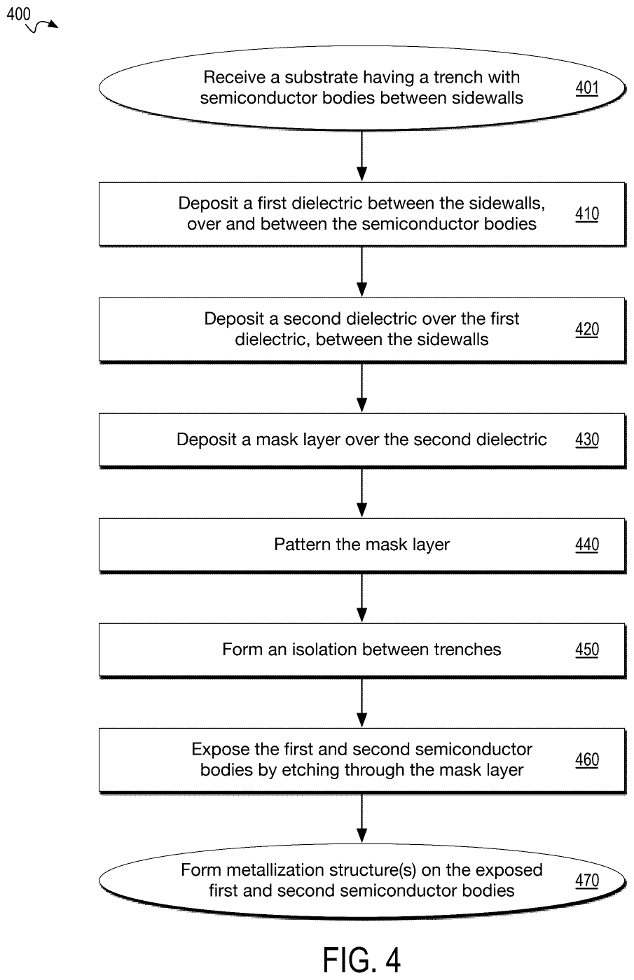

In many embodiments, dielectric 142 has an etch selectivity with adjacent structures, e.g., dielectrics 141, 143. An etch selectivity of dielectric 142 may provide protection (e.g., to dielectric 141), for example, during an etch process of a structure with a composition similar to that being etched. Similarly, dielectric 142 (and an etch selectivity of dielectric 142) may offer processing flexibility, for example, by enabling a selective (e.g., self-aligned) etch of a structure or material with a portion to be removed, as will be described later, e.g., at FIG. 4 and methods 400. Dielectric 142 may have any suitable thickness. In many embodiments, dielectric 142 has a thickness less than a thickness of dielectric 143 above dielectric 142. In some embodiments, layer 144 has a thickness of 10 nm or less. In some embodiments, dielectric 142 may have a minimal thickness, e.g., due to a planarization operation over substrate 199 or of an etch not completely selective to dielectric 142. In many embodiments, dielectric 142 includes oxygen. In some such embodiments, dielectric 142 includes aluminum (e.g., in an oxide of aluminum, AlₓO_{y}, such as Al₂O₃). Dielectric 142 may be of or include any suitable material(s).

In many embodiments, dielectric 143 has an etch selectivity with adjacent structures, e.g., dielectrics 141, 142. Dielectric 143 may act as a mask, as will be described later, e.g., at FIG. 4 and methods 400. In some embodiments, dielectric 143 is over dielectric 142, etc., including over materials and structures laterally adjacent to dielectric 142. For example, dielectrics 141, 142 may be between sidewalls (e.g., in the positive and/or negative x-directions) that dielectric 143 is over. In many embodiments, dielectric 143 includes nitrogen. In some such embodiments, dielectric 143 includes silicon (e.g., in a nitride of silicon, SiₓN_{y}). Dielectric 143 may be of or include any suitable material(s). In many embodiments, dielectric 143 has a thickness greater than a thickness of dielectric 142.

Conformal layer 144 includes a dielectric that may be distinct from each of dielectrics 141, 142, 143. In the embodiment of FIG. 1A, layer 144 is conformally on each sidewall 111 of all source or drain bodies 110. The term “sidewall” refers to a surface between top and bottom portions of bodies 110 and does not imply that that the surface is planar or perfectly vertical. For example, sidewalls 111 may be non-planar surfaces having multiple curves, e.g., being convex or bulging outwards where level with a nanoribbon region 120 and being concave between nanoribbon regions 120.

Two thicknesses of layer 144 are between each pair of adjacent bodies 110, one thickness on each sidewall 111 between the pair of bodies 110. In the case of a pair not coupled by metallization structure 130 (e.g., the central pair in the view of FIG. 1A), dielectric 141 is between the two thicknesses of layer 144 on adjacent sidewalls 111. In some such embodiments (as is shown in FIG. 1A), conformal layer 144 is under dielectric 141 between adjacent pairs of sidewalls 111, for example, in a continuous layer 144 connecting the two thicknesses of layer 144. In some embodiments, conformal layer 144 is a continuous layer 144 between adjacent pairs of sidewalls 111 of bodies 110, on a sidewall of trench 115 connecting the two thicknesses of layer 144.

In many embodiments, conformal layer 144 is a liner layer 144, e.g., protecting source and drain bodies 110 from dielectric 141. In some such embodiments, dielectric 141 is or includes an oxide that may react with (for example, degrade) bodies 110. In some embodiments, layer 144 has an etch selectivity with adjacent structures, e.g., dielectric 141, which may serve an etch-stop function, for example, when removing portions of dielectric 141. In some embodiments, layer 144 includes, or has a composition similar to, dielectric 143. In many embodiments, layer 144 includes nitrogen. In some such embodiments, layer 144 includes silicon (e.g., in a nitride of silicon, SiₓN_{y}). In many embodiments, dielectric 143 has a thickness greater than a thickness of layer 144. In many embodiments, dielectric 142 has a thickness greater than a thickness of layer 144. In some embodiments, layer 144 has a thickness of 4 nm or less.

Layer 144 may be a conformal liner layer 144 in trench 115. Layer 144 may be conformal over bodies 110. In some embodiments, layer 144 is conformal over spacer(s) 121 and/or 122, for example, in a bottom of trench 115 (as shown in FIG. 1A) and sidewalls of trench 115 (e.g., in both the positive and negative x-directions from the viewing plane). Device 100 may include one or both of spacers 121, 122, which may be conformal layers of dielectric material, e.g., lining the sidewalls and bottom of trenches 115. Trench 115 may include conformal spacers 121, 122, or trench 115 may be within spacers 121, 122. Spacers 121, 122 may be layers of dielectric material(s) and may have an etch selectivity. For example, one of spacers 121, 122 may include oxygen (and/or more oxygen than the other), and the other of spacers 121, 122 may include nitrogen (and/or more nitrogen than the one). In many embodiments, spacers 121, 122 include silicon.

Source and drain material bodies 110 are electrically and physically coupled to ends of channel regions 120. Source and drain bodies 110 are impurity doped regions, e.g., semiconductor material doped with one or more electrically active impurities. In many embodiments, bodies 110 are either mostly silicon or mostly silicon germanium and with small quantities of donor or acceptor dopants. Impurity doped bodies 110 may have increased charge-carrier availabilities and associated conductivities. Source or drain material body 110 may be doped with an opposite type (e.g., n- or p-type) or of similar type to channel region 120. Source or drain body 110 may include a predominant semiconductor material, and one or more n-dopants (such as phosphorus, arsenic, or antimony) or p-type impurities (such as boron or aluminum). Other dopant materials may be used. Any suitable means of formation may be used. Material body 110 may be epitaxially grown semiconductor regions, for example, of a Group IV semiconductor material (e.g., Si, Ge, SiGe, GeSn alloy). Other semiconductor materials may be employed. Material body 110 is substantially crystalline. Source and drain material bodies 110 may be polycrystalline, e.g., having long-range order at least adjacent ends of channel regions 120 and merging or joining into a unitary body with few grain boundaries. Source and drain material bodies 110 may be substantially monocrystalline.

Source and drain bodies 110 may include an interface layer, e.g., with very low contact resistivity and for contacting metallization structures 130 over bodies 110. In many embodiments, source or drain bodies 110 include a highly conductive interface layer having one or more metals. For example, material bodies 110 of silicon (including bodies 110 of silicon germanium) may have a metal alloyed with silicon in an interface layer at a top of body 110. In some embodiments, body 110 includes an interface layer having titanium and silicon. In some embodiments, body 110 includes an interface layer having silicon and one of cobalt, nickel, ruthenium, platinum, or tungsten. Other metals may be deployed.

In many embodiments, at least some of transistor structures 101 are physically symmetrical about channel regions 120, and identifiers for source and drain material bodies 110 may be reversed interchangeably in many contexts. However, the classification of source and drain material body 110 may be by the electrical relationships of transistor structure 101 and body 110 to other components in a given circuit (e.g., and the consequent direction of current flow through structure 101 and material body 110).

Channel regions 120 may be any suitable structure. In the example of FIG. 1A, channel regions 120 are nanoribbon regions 120 over fins 125 in or on substrate 199, and source and drain bodies 110 are each coupled with multiple nanoribbon regions 120 in stacks. In some embodiments, stacks of regions 120 include more or fewer nanoribbons (e.g., three nanoribbons each). In some embodiments, rather than stacks, source and drain bodies 110 are coupled by single nanoribbon channel regions 120. Nanoribbon channel regions 120 may have any suitable width, including sufficiently narrow or wide widths to be characterized as nanowires or nanosheets, respectively. Nanoribbon regions 120 of complementary types (e.g., in n- and p-type structures 101) may have accordingly different widths, for example, to align conductances of transistor structures 101. In some embodiments, regions 120 are nanoribbons formed from fins 125 (e.g., as separated layers of fins 125). In other embodiments, channel regions 120 are in fins 125, for example, in continuous channel regions spanning a same height as the stacks of regions 120 shown in FIG. 1A.

Channel regions 120 may be of any suitable material(s), for example, one or more semiconductor materials. Channel regions 120 may be of silicon, germanium, silicon germanium (e.g., Si₁₋ₓGeₓ), a III-V alloy material (such as gallium arsenide or gallium nitride), or other materials. Suitable materials may include two-dimensional (2D) materials (e.g., transition-metal dichalcogenides (TMD)) or semiconductor films (e.g., of certain metal oxides). Channel region semiconductor materials may be doped with one or more electrically active impurities, e.g., to increase channel conductivities.

Metallization structure 130 is a conductive (e.g., metal) structure that contacts source or drain bodies 110. Structures 130 may couple source and drain bodies 110 (and transistor structures 101) to interconnect layers, e.g., in an interconnect network over transistor structures 101. Structures 130 may contact each of source and drain bodies 110 at an interface layer. Metallization structures 130 may include any suitable material(s). In some embodiments, structures 130 include a stack of two or more metal layers, e.g., where at least one included metal layer is a liner (e.g., conformal) layer 132, and at least one metal layer is a fill metal layer 131. In many embodiments, structures 130 include one or more of copper, gold, tantalum, cobalt, tungsten, ruthenium, molybdenum, aluminum, and nickel, including in alloys. In some embodiments, structures 130 include nitrides of metals, e.g., tantalum and titanium. Structures 130 may include other electrically conductive materials, including non-metals.

In the embodiment of FIG. 1A, each metallization structure 130 is over and between a pair of source or drain bodies 110 and couples the pair of bodies 110 and the corresponding transistor structures 101. Each metallization structure 130 includes an intervening portion 133 between the corresponding pair of source or drain bodies 110. Layers 144 are on sidewalls 111 of each body 110, e.g., on both sides of intervening portions 133, between each intervening portion 133 and both source or drain bodies 110 portion 133 is between. Intervening portions 133 are down to spacer 122 between bodies 110. Layers 144 on adjacent sidewalls 111 between coupled bodies 110 are not continuous under dielectric 141, between the adjacent sidewalls 111. Layers 144 on adjacent sidewalls 111 between coupled bodies 110 are interrupted by intervening portion 133 between adjacent sidewalls 111. In some embodiments, intervening portions 133 are down to spacer 121 between bodies 110.

Substrate 199 may include any suitable material or materials. In some examples, substrate 199 may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may refer specifically to a base material (for example, a thick base or layer of semiconductor material) that other materials (such as metals and dielectrics) are built up on. In some contexts, substrate 199 may refer to a base material layer and any build-up layers, etc., over the base. In many embodiments, substrate 199 includes a semiconductor material under bodies 110 and regions 120, and channel regions 120 are of the same semiconductor material. In some such embodiments, trenches 115 are cut through silicon channel regions 120 (e.g., nanoribbons) and into a silicon substrate 199. Substrate 199 may also include other semiconductor materials, metals, dielectrics, dopants, and other materials commonly found in semiconductor substrates.

Isolation 191 is in, on, or over substrate 199, between the bases of fins 125. Isolation 191 is a dielectric material and isolates channel regions 120 from channel regions 120 in or over adjacent fins 125. Isolation 191 may include a fill or bulk portion within a liner layer portion, as shown in FIG. 1A. Isolation 191 is advantageously a low-K dielectric material. In many embodiments, isolation 191 includes oxygen. In some such embodiments, isolation 191 includes silicon (e.g., in an oxide of silicon, SiₓO_{y}). In many embodiments, isolation 191 includes, or is of the same dielectric material as, dielectric 141.

FIG. 1B illustrates a cross-sectional profile view D-D′ of adjacent source and drain material bodies 110 over a substrate 199 and in transistor structures 101 and metallization structures 130 over individual bodies 110. The embodiment shown in FIG. 1B is similar to that of FIG. 1A, with each body 110 in a distinct n- or p-type transistor structure 101. Unlike the embodiment of FIG. 1A, adjacent n- and p-type structures 101 are not paired or coupled by the shown structures 130, which are separately on each of the respective source or drain bodies 110 of each structure 101.

As in the embodiment of FIG. 1A, metallization structures 130 are over and contact source or drain bodies 110 in respective structures 101. In the embodiment of FIG. 1B, stacks 140 of dielectrics 141, 142, 143 are between and separate adjacent bodies 110. Each of the four shown source or drain bodies 110 is contacted by an unshared one of four structures 130 over the body 110. Stacks 140 of dielectrics 141, 142, 143 are between and separate adjacent structures 130. For example, the center stack 140 is between the inner two bodies 110 and between the inner two structures 130. Each of the inner bodies 110 and structures 130 is between the central stack 140 and a next stack 140. Each pair of bodies 110 and structures 130 to either side of center stack 140 is separated by a stack 140 between the two bodies 110 and two structures 130. Each of the outer bodies 110 and structures 130 is between an outer stack 140 and a next stack 140 towards the center from the outer stack 140.

A conformal layer 144 is on sidewalls 111 and between each stack 140 and the two bodies 110 that stack 140 is between. Dielectric 141 in each stack is between conformal layer 144 on sidewalls 111 of both bodies 110 that stack 140 is between. For example, dielectric 141 in the center stack 140 is between the inner pair of bodies 110 and between layer 144 on the inner pair of sidewalls 111 of the inner pair of bodies 110. Layer(s) 144 are between center stack 140 and each of the inner pair of bodies 110. Dielectric 141 in a next stack 140 over is between each the left or right pair of bodies 110 and between layers 144 on the pair of sidewalls 111 internal to that pair of bodies 110. Layer(s) 144 are between that next stack 140 over and each of the adjacent pair of bodies 110. Conformal layer 144 is continuous under dielectric 141 in each stack between adjacent pairs of sidewalls 111 of adjacent bodies 110, for example, in a continuous layer 144 connecting thicknesses of layer 144 on adjacent, facing sidewalls 111.

FIGS. 2A, 2B, and 2C illustrate plan views of IC device 100 having a protective dielectric 142 in dielectric stacks 140 between adjacent metallization structures 130, in accordance with some embodiments. Dielectric stacks 140 are in trenches 115, between aligned metallization structures 130. Trench isolations 250, e.g., fin trench isolations (FTI), are between trenches 115, extending in the y-directions, in parallel with structures 130. The structures shown may continue beyond the edges of views of FIGS. 2A-2C, for example, isolations 250 in the y-directions and regions 120 in the x-directions.

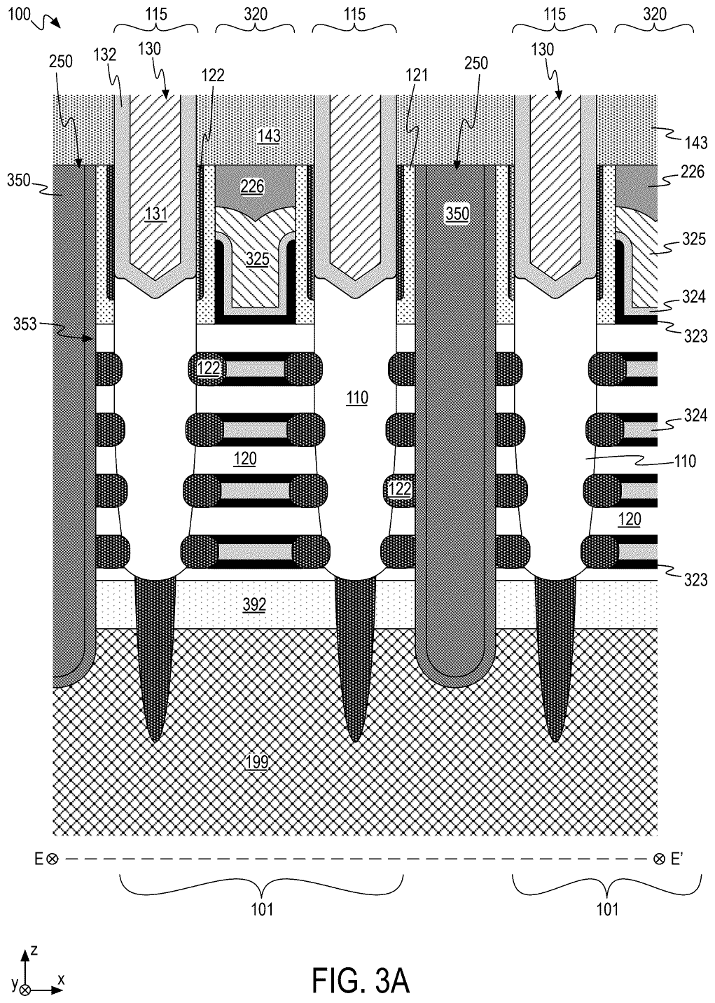

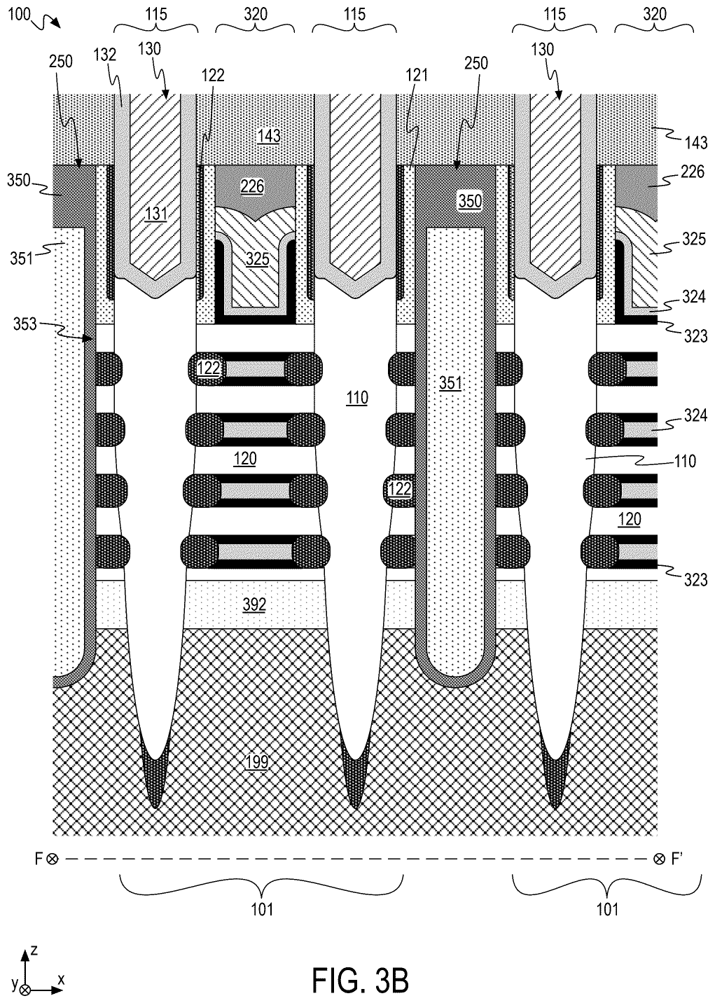

FIG. 2A, rather than a single x-y plane, shows a plan view of selected structures at various depths in device 100. Some structures and materials (e.g., dielectrics 141, 142, or 143) are not shown in the view of FIG. 2A for illustrative purposes, for example, so as to show the relative orientations of structures 101, 130, etc., without completely obscuring channel regions 120. The orientations and locations of profile views A-A′, D-D′, E-E′, F-F′ of FIGS. 1A, 1B, 3A, and 3B, respectively, are indicated in FIGS. 2A-2C. Profile views A-A′ and D-D′ are fin cuts of y-z planes through structures 130, as shown at FIGS. 1A and 1B. Profile views E-E′ and F-F′ are gate cuts of x-z planes through bodies 110 and channel regions 120, as shown at FIGS. 3A and 3B. Trench isolations 250 are between and separate arrays of transistor structures 101. In some embodiments, isolations 250 are between and separate arrays of identical (or at least similar) transistor structures 101. For example, the view A-A′ of FIG. 1A may also illustrate the four structures 101 in the positive x-direction from view D-D′, and isolation 250 may be between and separate arrays of identical transistor structures 101.

FIG. 2A illustrates the layout of channel regions 120 under gate contacts 226 and metallization structures 130 (over source and drain bodies). Gate contacts 226 extend in the y-directions, parallel and between metallization structures 130, e.g., together in transistor structures 101, over channel regions 120. Four transistor structures 101 include channel regions 120 (e.g., four stacks of nanoribbon channel regions 120) coupled to source and drain bodies under the two metallization structures 130 of view A-A′ and FIG. 1A, the same channel regions 120 coupled to source and drain bodies under the four metallization structures 130 of view D-D′ and FIG. 1B. The four structures 101 may be organized in two CMOS inverters, e.g., with complementary structures 101 coupled by shared structures 130 and shared gate contacts 226. The two metallization structures 130 of view A-A′ are parallel with the four metallization structures 130 of view D-D′.

Isolations 250 extend in the y-directions, parallel and between metallization structures 130, through channel regions 120. In some embodiments, isolations 250 interrupt or break the structures having channel regions 120, for example, stacks of nanoribbons that include channel regions 120. In some such embodiments, interrupted or broken nanoribbons contact isolations 250 on both sides (e.g., in the positive and negative x-directions) of isolations 250, and the interrupted or broken nanoribbons contact bodies 110 on both sides (e.g., in the positive and negative x-directions) of isolations 250 (e.g., under structures 130). Isolations 250 are between (e.g., in the x-directions) and separate transistor structures 101, for example, the four structures 101 in views A-A′ and D-D′ from four structures 101 in the positive x-direction.

IC device 100 (and structures 101) may be coupled to one or more power supplies on or through a host component 299 coupled to substrate 199. Host component 299 is a planar platform or substrate and may include dielectric and metallization structures. Host component 299 may mechanically support, and electrically couple to, substrate 199. At least one side of host component 299 includes interconnect interfaces, e.g., for soldering or direct bonding to one or more IC dies or other substrates. The opposite side of host component 299 may include similar interfaces or, e.g., copper pads for socketing or solder bumps for bonding to another substrate or host component, for example, a printed circuit board. Host component 299 may be any platform with interconnect interfaces, such as a package substrate or interposer, another IC die, etc. Host component 299 may itself be a die or an insulating substrate. Host component 299 may bond to any platform, such as a package substrate or interposer, another IC die, etc. In many embodiments, substrate 199 is an IC die, and host component 299 is a package substrate or interposer.

FIG. 2B shows view B-B′ at the top of trenches 115, horizontally through dielectric 142 and dielectric stacks 140 between adjacent metallization structures 130. Trenches 115 are indicated by dotted borders extending in the y-directions. Dielectric 142 is over dielectric 141 (not shown) in stacks 140. Dielectrics 141, 142 are in trench 115, between and in contact with sidewalls of trench 115 (e.g., of spacers 122). Dielectric 143 (not shown) is over dielectrics 141, 142 in stacks 140, but may extend over and beyond sidewalls of trench 115, e.g., in both the positive and negative x-directions (as described at FIG. 2C). Trench 115 is between (and formed by) adjacent gate structures (including gate contacts 226) over channel regions 120. Trenches 115 extend in the y-directions, between parallel sidewalls (e.g., of spacers 122) adjacent the gate structures, the sidewalls also extending in the y-directions. Spacers 121, 122 may form and contain trenches 115. Spacers 121 may be on sidewalls of gate structures (including gate contacts 226) and below trenches 115 and spacers 122. Spacers 122 may be on sidewalls of spacers 121 and below trenches 115.

Metallization structures 130 are in trenches 115 with dielectric 142 and dielectric stacks 140 between adjacent metallization structures 130. Dielectric stacks 140 isolate adjacent metallization structures 130 in a same trench 115. Spacers 121, 122 isolate metallization structures 130 from adjacent gate structures (including gate contacts 226). Adjacent gate contacts 226, e.g., between a pair of trenches 115, may be isolated by a dielectric material between contacts 226, for example, dielectric 141.

Isolations 250 extend in the y-directions, parallel and between spacers 121, 122 and structures 130, as well as in the z-direction, down through channel regions 120. Isolations 250 may be of a dielectric material that isolates (e.g., electrically) between adjacent structures, such as adjacent structures 101, 130 and source and drain bodies under structures 130. For example, isolations 250 isolate between transistor structures 101 and adjacent structures 101, e.g., in the x-directions. In many embodiments, the dielectric material of isolation 250 includes nitrogen. In some such embodiments, the dielectric material of isolation 250 includes silicon (e.g., in a nitride of silicon, SiₓN_{y}). In some embodiments, the dielectric material of isolation 250 includes oxygen. In some such embodiments, the dielectric material of isolation 250 includes silicon (e.g., in an oxide of silicon, SiₓO_{y}). In some embodiments, the dielectric material of isolation 250 includes nitrogen and oxygen. Note that profile views E-E′ and F-F′ at FIGS. 3A and 3B, respectively, are through and show isolations 250 in x-z cross-sectional viewing planes.

FIG. 2C illustrates view C-C′ horizontally through dielectric 143. Dielectric 143 in FIG. 2C is continuous over trenches 115, spacers 121, 122, dielectrics 141, 142, and isolation 250 (e.g., shown in FIG. 2B). Dielectric 143 is continuous over dielectrics 141, 142 of trench 115 and extends over and beyond sidewalls of trench 115 (e.g., spacers 122) in both the positive and negative x-directions.

Dielectric 143 may serve as a mask material during processing of device 100, e.g., during the formation of metallization structures 130 and gate vias or contacts 228. For example, structures 130 may be formed by etching dielectrics 141, 142 through patterned mask dielectric 143 and by depositing metallization in the formed openings. Gate vias or contacts 228 may be formed on or as part of a gate structure by depositing metallization in patterned openings in patterned mask dielectric 143. In the embodiments of FIGS. 2B and 2C, gate vias or contacts 228 have a smaller cross-sectional area than gate contacts 226 and may be formed in a separate operation after gate contacts 226. Note that profile views E-E′ and F-F′ at FIGS. 3A and 3B, respectively, are through dielectric 143 to either side (e.g., in the y-directions) of gate vias or contacts 228.

FIGS. 3A and 3B illustrate cross-sectional profile views E-E′ and F-F′ of IC device 100 having trench isolation 250 between source and drain bodies 110 and metallization structures 130, and extending down through nanoribbon regions 120, in accordance with some embodiments. Isolations 250 isolate adjacent trenches 115 and transistor structures 101. Isolations 250 are between and parallel to adjacent trenches 115 (e.g., extending in the y-directions). Gate structures 320 are between adjacent source and drain bodies 110 and metallization structures 130. FIGS. 3A and 3B show similar views E-E′ and F-F′ in x-z viewing planes of different structures for trench isolations 250.

FIG. 3A illustrates trench isolations 250 between source and drain bodies 110. In the embodiments of FIG. 3A, bodies 110 are p-type source and drain bodies 110. Isolation 250 may include a conformal liner layer of dielectric 350 (e.g., forming sidewalls 353 of isolation 250) and a fill or bulk portion of dielectric 350. Isolation 250 may be an integrated structure of dielectric 350, e.g., without a discrete interface between layer and fill portions of dielectric 350. Dielectric 350 may have an advantageously low relative permittivity, e.g., with a dielectric constant less than at least 9. In some embodiments, dielectric 350 has a dielectric constant less than 6. In many embodiments, dielectric 350 includes nitrogen. In some such embodiments, dielectric 350 includes silicon (e.g., in a nitride of silicon, SiₓN_{y}). Dielectric 350 including a nitride of silicon may advantageously provide strain (e.g., compressive strain) to channel regions 120, which may increase electrical conductivity through regions 120. Dielectric 350 may be of or include any suitable material(s). Isolations 250 interrupt or break stacks of nanoribbon structures having channel regions 120. Interrupted or broken nanoribbons contact isolations 250 between spacers 122 on both sides (e.g., in the positive and negative x-directions) of isolations 250, and the interrupted or broken nanoribbons contact bodies 110 between spacers 122 on both sides (e.g., in the positive and negative x-directions) of isolations 250 (e.g., under structures 130). Isolations 250 are between (e.g., in the x-directions) and separate transistor structures 101.

Source and drain bodies 110 and metallization structures 130 are in trenches 115. Dielectrics 141, 142 (e.g., not shown in FIG. 3A, but as described at FIGS. 1A, 2B) are in trench 115, e.g., in both the positive and negative y-directions of the viewing plane. Dielectric 143 is over dielectrics 141, 142 (e.g., out of the viewing plane), but extends over and beyond sidewalls of trench 115, as shown, in both the positive and negative x-directions. Trenches 115 extend in the y-directions, between parallel sidewalls of adjacent gate structures 320.

Transistor structure 101 includes a gate electrode 324 and gate dielectric 323 in gate structure 320 over and adjacent channel regions 120. Gate structure 320 includes gate dielectric 323 on channel region 120, e.g., on and around each nanoribbon. Gate structure 320 includes gate electrode 324 between adjacent metallization structures 130 (e.g., over each source or drain body 110), and with gate dielectric 323 between gate electrode 324 and each channel region 120 (e.g., nanoribbons). Gate dielectric 323 provides electrical insulation between channel region 120 and gate electrode 324, and enables electrostatic control of channel region 120 (and of the conduction of region 120) by an electric signal on gate electrode 324. Conduction of channel region 120 may electrically couple adjacent source and drain bodies 110 and the respective metallization structures 130 coupled to bodies 110. Gate structure 320 may include a fill or bulk portion 325 that couples a layer of gate electrode 324 with gate contact 226. In the embodiments of FIG. 3A, dielectric 143 is visible in front of (e.g., in the y-directions), and obscuring, gate vias or contacts 228, which couple gate electrode 324, etc., to interconnect layers, e.g., in an interconnect network over transistor structures 101.

Gate dielectric 323 may have more than one layer. Gate dielectric 323 may be of any suitable material(s). The one or more layers of gate dielectric 323 may include a silicon oxide, silicon dioxide (SiO₂), a silicon oxynitride, etc. Advantageously, gate dielectric 323 includes a high-permittivity (“high-K”) dielectric (for example, having a dielectric constant over 6). A high-K dielectric material may include one or more of various elements, such as hafnium, silicon, oxygen, titanium, tantalum, lanthanum, aluminum, zirconium, barium, strontium, yttrium, lead, scandium, niobium, and zinc. Gate dielectric 323 may include a dopant, e.g., for elevated permittivity.

Gate electrode 324 is on gate dielectric 323 and may include of at least one of a p- or an n-type work function metal (WFM), depending on whether the transistor is a pMOS or nMOS transistor. In some embodiments, gate electrode 324 is a stack of two or more metal layers, where one or more metal layers are WFM layers and at least one metal layer is a fill metal layer. In a pMOS transistor, for example, metals that may be utilized for gate electrode 324 include, but are not limited to, ruthenium, palladium, platinum, cobalt, nickel, and conductive metal oxides, e.g., ruthenium oxide. A p-type metal layer will enable the formation of a pMOS gate electrode 324 with a work function that is between about 4.9 eV and about 5.2 eV. These or other metals may be deployed in gate electrode 324 in an nMOS transistor, including hafnium, zirconium, titanium, tantalum, aluminum, alloys of these metals, carbides of these metals (such as hafnium carbide, zirconium carbide, titanium carbide, tantalum carbide), etc. An n-type metal layer will enable the formation of an nMOS gate electrode 324 with a work function that is between about 3.9 eV and about 4.2 eV.

Spacers 121, 122 provide isolation between source and drain material bodies 110 and gate electrodes 324. Spacer 122 is in contact with bodies 110 and gate electrodes 324. Spacer 122 is also between and in contact with channel regions 120 between source and drain bodies 110 and gate electrodes 324. Spacer 122 is in contact with structures 130 (e.g., at layer 132) and provides isolation between metallization structures 130 and gate contact 226 and electrode 324. Spacer 121 is in contact with gate contact 226 and electrode 324 (and portion 325) and provides isolation between metallization structures 130 and gate contact 226 and electrode 324. Spacers 121, 122 may be of any suitably insulating material(s), advantageously a low-K dielectric to minimize parasitic coupling between adjacent bodies 110 and gate electrodes 324, and between adjacent structures 130 and electrodes 324. In some embodiments, spacer 122 in contact with structure 130 is of the same electrically insulating material as spacers 122 in contact with body 110 and gate electrodes 324 between channel regions 120. In some embodiments, a dielectric layer having a same composition as layer 144 is between metallization structures 130 and spacer 122, over body 110.

FIG. 3B shows trench isolations 250 of multiple dielectrics 350, 351 between n-type source and drain bodies 110. In some embodiments, isolations 250 include a liner layer of dielectric 350 (e.g., forming sidewalls 353) and a fill or bulk portion of dielectric 351. Dielectric 351 may be a low-K dielectric 351. In many embodiments, dielectric 351 includes oxygen. In some such embodiments, dielectric 351 includes silicon (e.g., in an oxide of silicon, SiₓO_{y}). In some embodiments, dielectric 351 is the same dielectric material as dielectric 141. Dielectric 351 may offer different strain characteristics, which may provide improved conductivity through channel regions 120.

FIG. 4 is a flow chart of methods 400 for forming metallization structures adjacent protective dielectric material that enables self-aligned isolations, in accordance with some embodiments. Methods 400 include operations 401-470. Some operations shown in FIG. 4 are optional. Additional operations may be included. FIG. 4 shows an example sequence, but the operations can be done in other orders as well, and some operations may be omitted. Some operations can also be performed multiple times before other operations are performed. For example, first and second dielectrics may be deposited between sidewalls in any number of trenches (e.g., at operations 410, 420) before forming an isolation between trenches, or a trench isolation may not necessarily be formed. Multiple mask layers may be deployed (e.g., at operations 430). Some operations may be included within other operations so that the number of operations illustrated FIG. 4 is not a limitation of the methods 400.

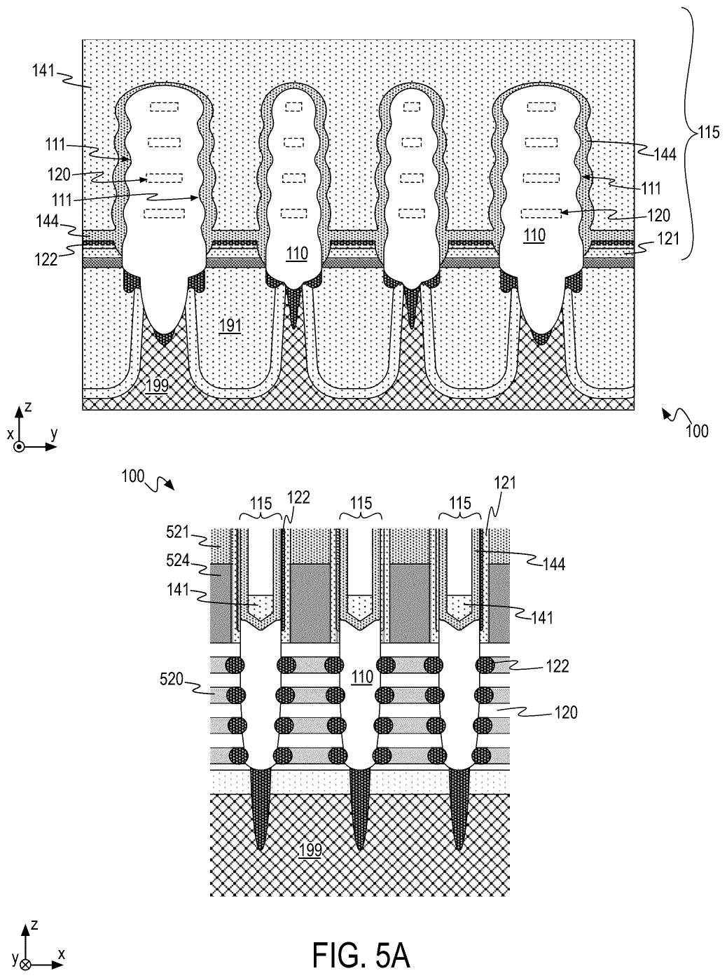

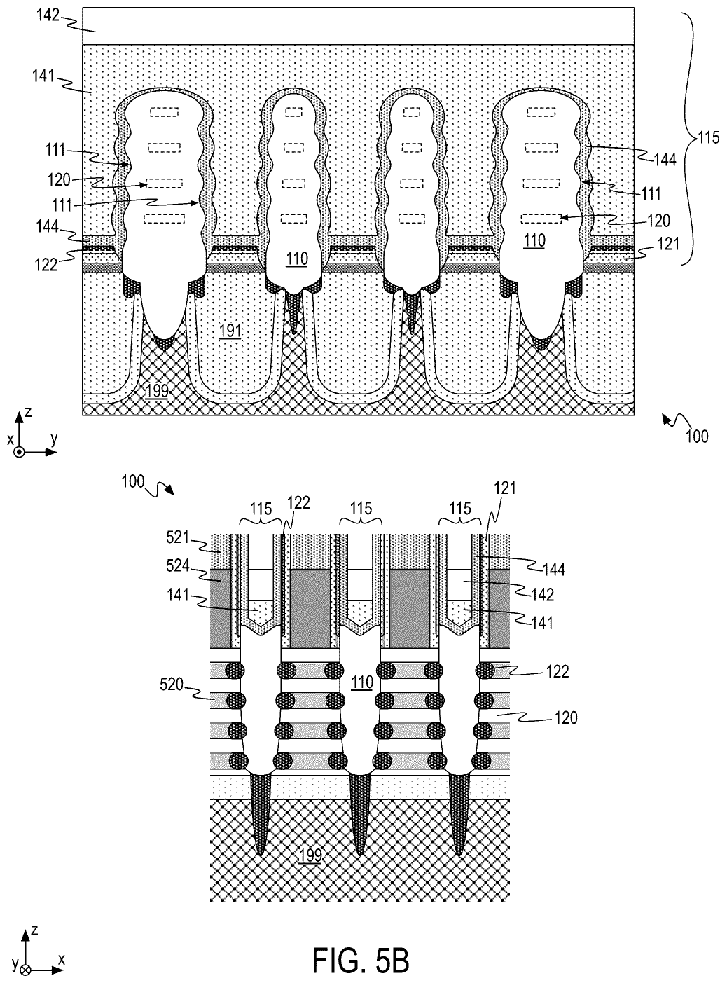

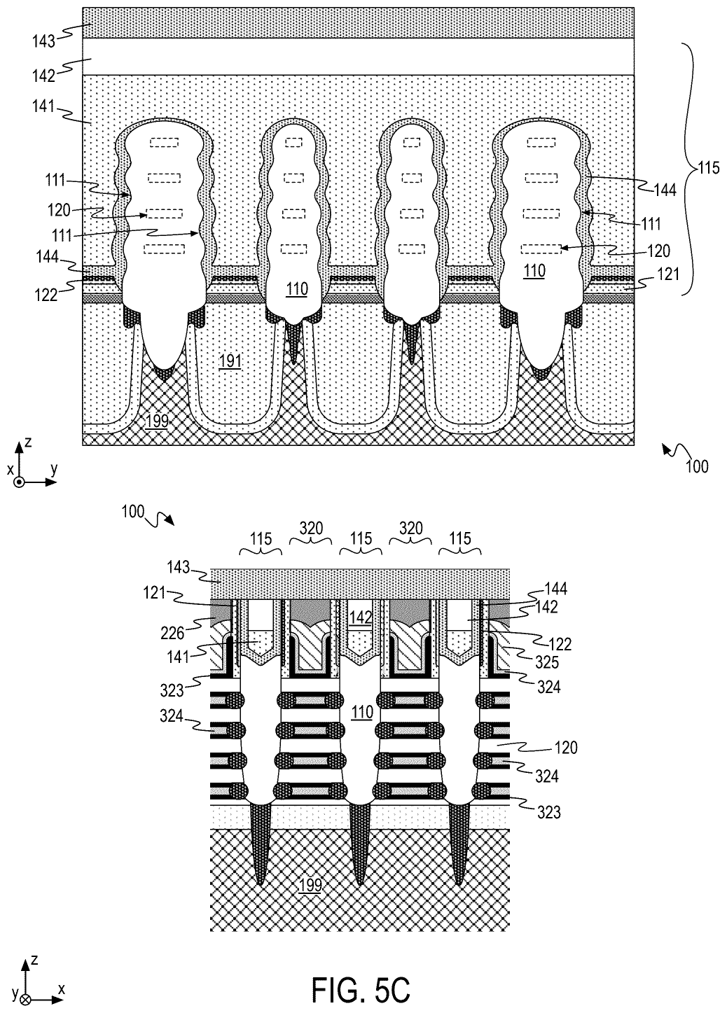

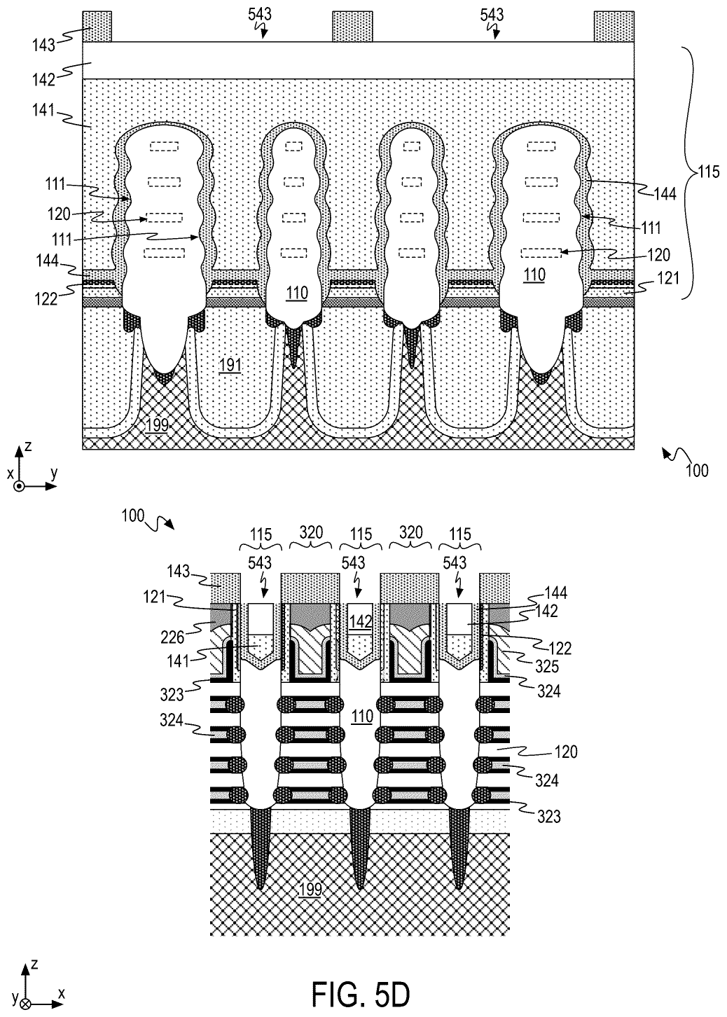

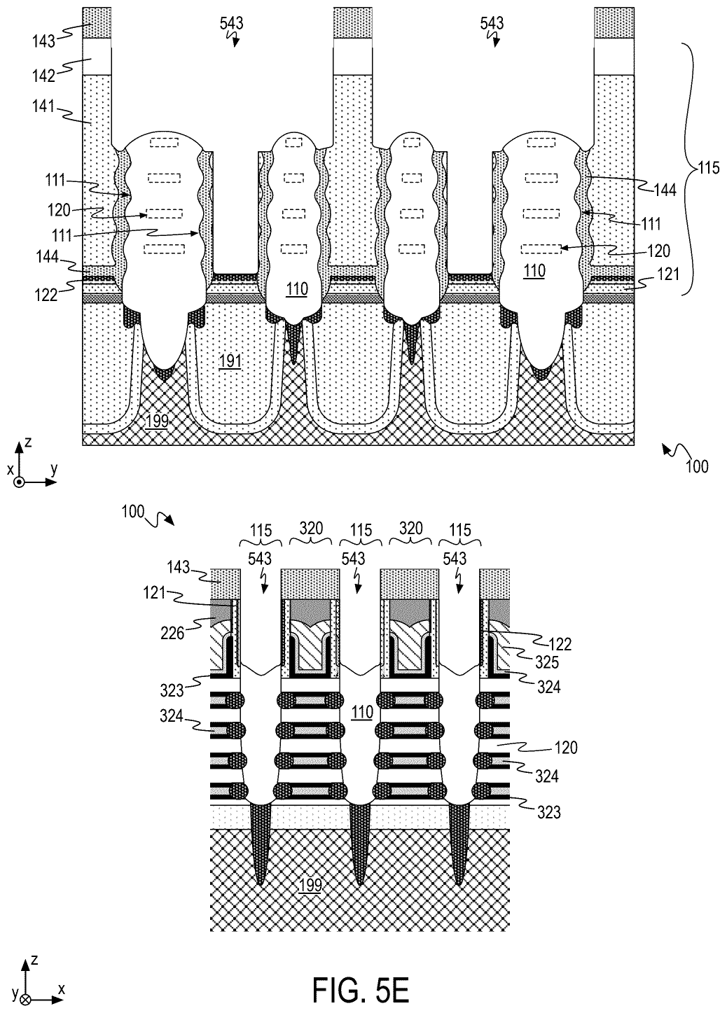

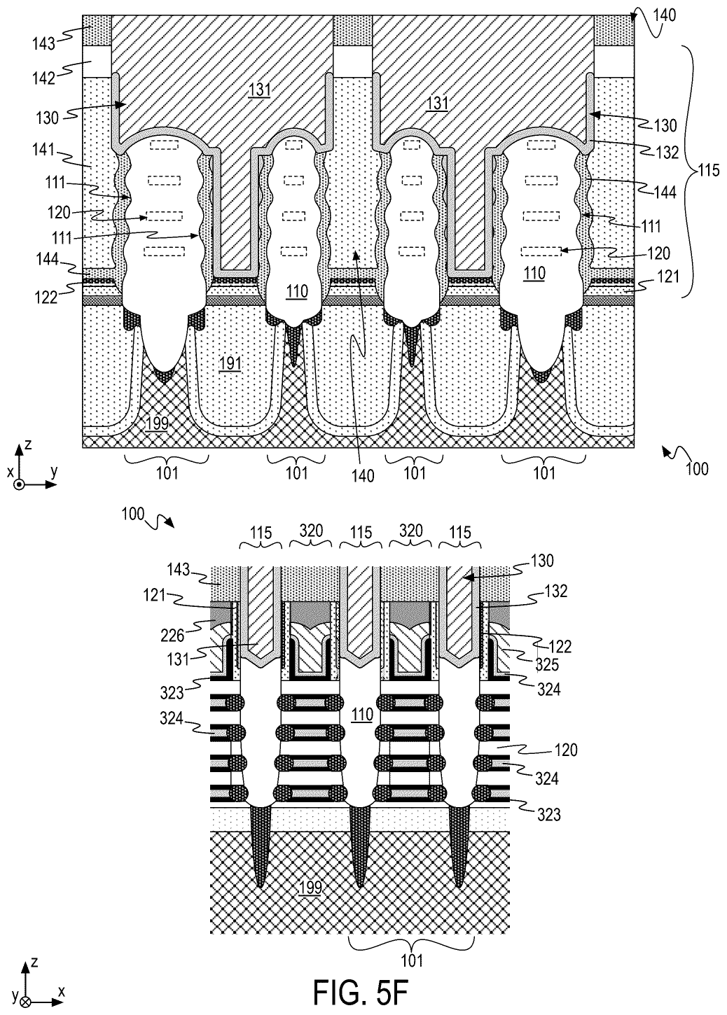

FIGS. 5A, 5B, 5C, 5D, 5E and 5F illustrate cross-sectional profile views of transistor structures 101 coupled to metallization structures 130 adjacent dielectric stacks 140 having a protective dielectric 142, at various stages of manufacture, in accordance with some embodiments. FIGS. 5A-5F show possible examples of intermediate structures during an embodiment of a practice of methods 400 of FIG. 4.

Returning to FIG. 4, methods 400 begin at operation 401 with receiving a substrate. In some embodiments, the substrate includes source and drain material bodies coupled to channel regions. The source and drain bodies may be semiconductor bodies (for example, much as bodies 110 are described at FIG. 1A and elsewhere). In some embodiments, the source and drain bodies are in trenches between gate structures on and over the channel regions. For example, the gate structures may be dummy or sacrificial gate structures (e.g., of polycrystalline silicon), gate structures with gate electrodes (e.g., of WFM) on a gate dielectric, etc. The trenches may have sidewalls on or formed by the gate structures, for example, sidewalls of spacer dielectrics over or on the gate structures. In some embodiments, a thin dielectric layer is conformally on and over the source and drain bodies, e.g., on tops and sidewalls of the source and drain bodies (for example, much as layer 144 is described at FIG. 1A and elsewhere).

Methods 400 continue with depositing a first dielectric over and between the source and drain bodies at operation 410. In some embodiments, the first dielectric is deposited between the sidewalls of a trench over the substrate, over and between the source or drain bodies in the trench. The first dielectric may be any suitable material, such as a low-K dielectric material (for example, much as dielectric 141 is described at FIG. 1A and elsewhere). The first dielectric may be deposited (e.g., grown by thermal oxidation) by any suitable means, for example, a chemical vapor deposition (CVD), etc. The first dielectric may be deposited to any suitable height, e.g., below a top of the trench and sidewalls. In some embodiments, the first dielectric is deposited to a first height (e.g., at or over a top of the trench and sidewalls) before being recessed down to a second height below the first height (e.g., below a top of the trench and sidewalls).

In some embodiments, for example, before depositing the first dielectric, a dielectric layer is conformally deposited over the source and drain bodies. In some such embodiments, when depositing the first dielectric over and between the source and drain bodies, the first dielectric is deposited over and within the conformally deposited dielectric layer. The conformally deposited dielectric layer may have any suitable composition (for example, much as layer 144 is described at FIG. 1A and elsewhere) and may be deposited by any suitable means (e.g., CVD, an atomic layer deposition (ALD), etc.). The conformally deposited dielectric layer may have a composition different from a composition of the first dielectric, and there may be an etch selectivity between the first dielectric and the conformal dielectric layer (for example, much as described at FIG. 1A and elsewhere between dielectric 141 and layer 144). In some embodiments, the first dielectric includes silicon and oxygen, and the conformal dielectric layer includes silicon and nitrogen.

FIG. 5A illustrates first dielectric 141 over source and drain material bodies 110 in trench 115 in a workpiece or device 100, in accordance with some embodiments, for example, following a performance of depositing operation 410. First dielectric 141 is in trench 115 and up to a height below a top of trench 115 and sidewalls of trench 115. First dielectric 141 is over conformal dielectric layer 144, which is conformally over bodies 110 (e.g., on sidewalls 111 of bodies) and spacers 121, 122 at a bottom of trench 115. First dielectric 141 is over layer 144 and spacers 121, 122 at a bottom of trench 115. Spacers 121, 122 are over isolation 191 below trench 115 and in, on, or over substrate 199. Source and drain bodies 110 are coupled to channel regions 120 (indicated by dashed lines and not in the visible y-z plane).

Channel regions 120 can be seen in the gate-cut, x-z plane. First dielectric 141 is over conformal dielectric layer 144, in trench 115 to a height below a top of trench 115. Conformal dielectric layer 144 is over bodies 110 and on sidewall spacers 121, 122 of trench 115. In the embodiment of FIG. 5A, dummy gate 524 is over channel regions 120, and mask material 521 is over dummy gate 524. Sacrificial material 520 is between channel regions 120, which have not been released.

Returning to FIG. 4, methods 400 continue with depositing a second dielectric over the first dielectric between the first and second sidewalls at operation 420. The second dielectric may be any suitable material (for example, much as dielectric 142 is described at FIG. 1A and elsewhere), e.g., having an etch selectivity with the first dielectric material. The second dielectric may be deposited by any suitable means, for example, by CVD, ALD, etc. In many embodiments, the second dielectric includes oxygen. In some such embodiments, the second dielectric includes aluminum (e.g., in an oxide of aluminum, AlₓO_{y}, such as Al₂O₃). The second dielectric may be of or include any suitable material(s). The second dielectric may be deposited to any suitable height, e.g., to or below a top of the trench and sidewalls. In some embodiments, the second dielectric is deposited to a first height (e.g., at or over a top of the trench and sidewalls) before being recessed down to a second height below the first height (e.g., at or below a top of the trench and sidewalls). In some embodiments, the second dielectric is deposited to certain height, but the second dielectric is subsequently reduced in height, e.g., when shielding the first dielectric from (and being subjected to) an etch.

FIG. 5B show first and second dielectrics 141, 142 over source and drain material bodies 110 in trench 115 in a workpiece or device 100, in accordance with some embodiments, for example, following a performance of depositing operation 420. Second dielectric 142 is in trench 115 and up to a height below a top of trench 115 and sidewalls of trench 115. First and second dielectrics 141, 142 are over conformal dielectric layer 144. First dielectric 141 is over layer 144 and spacers 121, 122 at a bottom of trench 115. First and second dielectrics 141, 142 are over conformal dielectric layer 144, which is on sidewall spacers 121, 122 of trench 115.

Returning to FIG. 4, methods 400 continue at operation 430 with depositing a mask layer (e.g., a third dielectric) over the second dielectric. In many embodiments, the mask layer is a third dielectric deposited over the entire substrate, over the trench and outside of the trench. In many embodiments, the mask layer is deposited to remove (e.g., etch out) portions of first and second dielectrics in one or more trenches to expose the source and drain bodies for subsequent contacting. In some such embodiments, the mask layer is deposited following a planarization operation, e.g., that lowers or recesses a top surface of the substrate to a top of the trench (which may also be recessed). In some embodiments, the mask layer is deposited to etch between one or more pairs of trenches, through channel regions and, e.g., a dummy gate, for example, to form a trench isolation between trenches. In some embodiments, for example, to form a metallization structure (e.g., a contact) over and on the source or drain bodies, the mask layer is deposited after a sacrificial dummy gate is removed and replaced with an operational gate structure (e.g., having a gate electrode on a gate dielectric). The mask layer may be any suitable material, such as a dielectric material (for example, much as dielectric 143 is described at FIG. 1A and elsewhere). The mask layer may be deposited by any suitable means, for example, by CVD, ALD, etc.

In many embodiments, the mask layer is a dielectric and includes nitrogen. In some such embodiments, the mask layer includes silicon (e.g., in a nitride of silicon, SiₓN_{y}). The mask layer may be of or include any suitable material(s). Multiple mask layers may be deposited and with different compositions. The mask layer may be deposited to any suitable height, e.g., to above a top of the trench and sidewalls. In many embodiments, the mask layer is deposited over the entire substrate, starting at a top of the trench and building up from there. In many embodiments, the mask layer has a thickness greater than a thickness of the second dielectric. The thickness of the mask layer as deposited may depend on the quantity and duration(s) of the etch(es) to be performed through the mask layer, as well as on the etch selectivity to the mask layer.

FIG. 5C illustrates third or mask dielectric 143 over first and second dielectrics 141, 142 in trenches 115 and over gate structures 320 between trenches 115 in a workpiece or device 100, in accordance with some embodiments, for example, following a performance of depositing operation 430. Dielectric 143 is over and on a surface collectively made up of spacers 121, 122, dielectrics 142, layers 144, and gate contacts 226, for example, following a planarization operation on a top surface of workpiece or device 100. Dielectrics 141, 142 are in trenches 115, e.g., extending in both the positive and negative y-directions. Dielectric 143 is over dielectrics 141, 142, but extends in both the positive and negative x- and y-directions, over and beyond sidewalls of trench 115.

Returning to FIG. 4, methods 400 continue with patterning the mask layer at operation 440. The mask layer may be patterned using any suitable means. In many embodiments, the mask layer is patterned using photolithographic masks and one or more mask layers (e.g., at least one layer of photoresist), for example, a hard mask layer (e.g., including carbon), a bottom anti-reflective coating (BARC), etc. The mask layer may be patterned to have openings of any suitable size and location. In many embodiments, the mask layer is patterned to have openings over source and drain bodies, e.g., to expose the source and drain bodies, either with openings particular to each body or with larger openings shared by multiple bodies to be coupled by a metallization structure. In some embodiments, the mask layer is patterned to have openings over gate structures, e.g., to expose gate structures (e.g., electrodes or contacts) to be contacted by a gate contact or via.

FIG. 5D illustrates openings 543 in mask dielectric 143 over dielectrics 141, 142 in a workpiece or IC device 100, in accordance with some embodiments, for example, following a performance of patterning operation 440. Openings 543 in mask dielectric 143 are over trenches 115. Mask dielectric 143 is present over gate structures 320. In some embodiments, mask dielectric 143 has openings 543 over gate contacts 226. In some such embodiments, openings 543 in mask dielectric 143 over gate contacts 226 are in front or behind the visible x-z plane, e.g., in the positive or negative y-direction.

Returning to FIG. 4, methods 400 optionally continue with forming an isolation between trenches at operation 450. In some embodiments, a mask layer is patterned (e.g., at operation 440) to enable an etch through (e.g., nanoribbon) channel regions, between trenches, for example, to form an isolation. This patterning may be separate from (e.g., before) patterning a mask layer for forming metallization structures. Some semiconductor regions, such as nanoribbon regions, may be referred to as “channel regions” in the context of forming an isolation structure (e.g., much like isolation 250 as described at FIGS. 3A, etc.) despite the semiconductor regions, e.g., nanoribbons, not being utilized as channels, but instead being etched or cut through.

Forming an isolation at operation 450 may advantageously be after depositing the second dielectric over the first dielectric. A protective, second dielectric (for example, much as dielectric 142 is described at FIG. 1A and elsewhere), e.g., having an etch selectivity with the first dielectric material, may provide a certain measure of self-alignment and protection of trenches (including the first dielectric in the trenches). For example, a protective, second dielectric over trenches (e.g., having source and drain bodies) adjacent and to both sides of a dummy gate and channel regions to be etched or cut through may protect the trenches (including the first dielectric over the source and drain bodies) beneath the protective, second dielectric.

In addition to a high-energy etch or cut to form an opening into or through the channel regions between the protected trenches, multiple etches to remove a dielectric deposited in the opening may (e.g., in conventional methods) also unintentionally remove the first dielectric over the source and drain bodies in the trenches. In many embodiments, the first dielectric over the source and drain bodies in the trenches is the same dielectric material as (or very similar to) the dielectric material deposited and removed from openings formed for trench isolations. Without the protective dielectric, some of the first dielectric may be removed and then covered with another dielectric used for forming the isolation. The other, isolation dielectric will not necessarily be removed when removing the first dielectric to expose source and drain bodies. Accordingly (e.g., in conventional methods), following forming a trench isolation, attempts to expose source and drain bodies may be unsuccessful (and defects may be formed, causing yield, performance, and reliability degradations) if a protective, second dielectric is not used to shield the susceptible first dielectric.

As an example, using FIGS. 1B, 2A-2C, 3A and 3B, and 5B, etc., as a reference, isolation 250 (e.g., between trenches 115 in FIGS. 3A and 3B) may have been formed by methods 400 and operation 450. Isolation 250 extends in y-directions through multiple stacks of nanoribbon regions 120 and in the z-direction through multiple nanoribbon regions 120 in a single stack. Trenches 115 to either side of isolation 250 have sidewalls (e.g., on spacers 122 and below on regions 120, etc.), as shown at FIGS. 2B, 3A, 3B. First and second semiconductor bodies 110 are in the center trench 115 of FIGS. 3A and 3B (and also in the left pair of bodies 110 in view D-D′ of FIG. 1B, under structures 130 in FIGS. 2A-2C), and third and fourth semiconductor bodies 110 are in the right trench 115 of FIGS. 3A and 3B (and under structures 130 in FIGS. 2A-2C). First and second semiconductor bodies 110 are between first and second sidewalls over substrate 199 (extending in the y-directions), and third and fourth semiconductor bodies 110 are between third and fourth sidewalls over substrate 199 (extending in the y-directions).

Forming an opening at operation 450 for a trench isolation may advantageously be with the second dielectric present in trenches over the first dielectric, for example, as shown at FIG. 5B in trenches 115 and over source and drain bodies 110 (and over and within conformal layer 144). First dielectric 141 may have been deposited (e.g., before structures 130 were formed, at operation 410) between the first and second sidewalls, over and between the first and second semiconductor bodies 110. First dielectric 141 may have also been deposited (e.g., at operation 410) between the third and fourth sidewalls, over and between third and fourth semiconductor bodies 110. Second dielectric 142 may have been deposited (e.g., before structures 130 were formed, at operation 420) between the first and second sidewalls, over first dielectric 141, over first and second semiconductor bodies 110. Second dielectric 142 may have also been deposited (e.g., at operation 410) between the third and fourth sidewalls, over and between third and fourth semiconductor bodies 110.

Here, at operation 450, methods 400 may further include forming an opening (e.g., for isolation 250) by etching between the second sidewall (of center trench 115) and third sidewall (of right trench 115). Any suitable means for etching may be used. In some embodiments, an anisotropic, dry etch, e.g., a reactive-ion etch (RIE), such as a deep RIE (DRIE), between the second and third sidewalls forms the opening down to substrate 199. The opening may extend, e.g., in the y-directions, through (and interrupt or break) multiple channel regions (e.g., stacks of nanoribbons). The opening may extend, e.g., in the z-directions, through (and interrupt) multiple channel regions (e.g., nanoribbons in a stack) and a gate structure. In some embodiments, the opening extends through a dummy gate structure.

The etching between the second and third sidewalls may be aided by a protective, second dielectric over adjacent trenches (e.g., between the first and second sidewalls and between the third and fourth sidewalls). The protective, second dielectric may shield the first dielectric from the etch. The protective, second dielectric may also funnel or bracket the etch between the second dielectric in both adjacent trenches, which may serve to make the etch self-aligned (at least somewhat). Besides shielding the adjacent trenches, this funneling or bracketing may enable an optimization or balancing of patterning requirements, for example, by relaxing an overly tight patterning that might result in too narrow an opening (e.g., in which subsequent depositions might be incomplete).

Here, at operation 450, methods 400 may further include conformally depositing a dielectric over and in the opening, for example, on the bottom and sidewalls of the opening. In many embodiments, the dielectric conformally deposited in the opening has an etch selectivity with (and a composition different than) the first and second dielectrics (e.g., dielectrics 141, 142 of FIGS. 1A and 1B). In some embodiments, the dielectric conformally deposited in the opening has an etch selectivity with (and a composition different than) the third dielectric (e.g., dielectric 143 of FIGS. 1A and 1B).

Here, at operation 450, methods 400 may further include depositing a dielectric in the opening between the second and third sidewalls. In many embodiments, the dielectric deposited in the opening is the first dielectric (e.g., dielectric 141 between and below structures 130 at FIG. 1B). In many embodiments with a dielectric already conformally deposited in the opening, a dielectric other than the conformally deposited dielectric (e.g., having an etch selectivity with (and a composition different than) the conformally deposited dielectric) is deposited between the second and third sidewalls (for example, in and between the conformally deposited dielectric on and between the second and third sidewalls). In some such embodiments, the first dielectric (e.g., dielectric 141 of FIGS. 1A and 1B) is deposited in and between the conformally deposited dielectric on and between the second and third sidewalls).

Here, at operation 450, methods 400 may further include removing a portion of the dielectric between source and drain bodies across the dielectric(s) deposited in the opening, (between the second and third sidewalls). In some embodiments, dielectric is removed (e.g., recessed) down to a height still above the interrupted or broken channel regions. In some such embodiments, the recessed dielectric is the first dielectric (e.g., dielectric 141), retained between n-type source and drain bodies 110. In some embodiments, all of a fill dielectric within a liner (e.g., conformal) dielectric is removed from the opening. In some such embodiments, the removed dielectric is the first dielectric (e.g., dielectric 141 of at least silicon and oxygen), and the retained, conformal, liner dielectric includes a nitride (e.g., more nitrogen than dielectric 141 and less oxygen) retained between p-type source and drain bodies 110. In some embodiments, the first dielectric (e.g., dielectric 141) is first recessed concurrently between both n- and p-type source and drain bodies, then the first dielectric is masked over between n-type source and drain bodies, the first dielectric is then completely removed between p-type source and drain bodies 110, and the first dielectric is unmasked (e.g., exposed) between n-type source and drain bodies. These removal etches (including recessing) may be aided by a protective, second dielectric over adjacent trenches, as previously described, for example, when the dielectric to be removed is the first dielectric by a selective etch. In these cases, the protective, second dielectric in the trenches having an etch selectivity with the (shielded) first dielectric in the trenches may be particularly beneficial.

Here, at operation 450, methods 400 may further include depositing a dielectric between the second and third sidewalls. In many embodiments, the dielectric deposited in the opening is the conformally deposited dielectric, and the conformally deposited dielectric now fills the opening, e.g., over and/or in the place of the removed dielectric. For example, the conformally deposited liner dielectric (e.g., including nitrogen) may fill completely fill the opening and form the isolation between trenches having p-type source and drain bodies, and the conformally deposited liner dielectric (e.g., including nitrogen) may fill the opening over the first dielectric (e.g., dielectric 141 with little or no nitrogen content) between trenches having n-type source and drain bodies and form the isolation with at least two distinct dielectrics. These deposited dielectrics may advantageously optimize conductances in channel regions aligned with the deposited dielectrics (e.g., isolations 250), for example, by exerting strain on the channel regions (e.g., a compressive strain from nitride dielectrics between and to both sides of p-type channels.

Methods 400 continue at operation 460 by exposing the source and drain material bodies by etching through the mask layer. The source and drain bodies may be exposed by any suitable etch, e.g., an etch at least somewhat selective to the mask layer. In some embodiments, an anisotropic, dry etch, e.g., a RIE, such as a DRIE, that is selective to the mask layer is utilized to remove the first and second dielectrics from over the source and drain bodies. The removed first and second dielectric material may be that material not covered by the mask layer, e.g., under or in the openings in the mask layer. In some such embodiments, the openings in the mask layer are over multiple source and drain bodies and the area between the multiple bodies. In at least some such embodiments, sufficient first and second dielectric material is removed over and between the multiple bodies to form a metallization structure (e.g., a contact) over, between, and coupling the multiple bodies. In embodiments having a conformally deposited dielectric layer on and over the source and drain bodies, the conformally deposited dielectric layer on and over the source and drain bodies is removed with the removed first and second dielectric material not covered by the mask layer, e.g., under or in the openings in the mask layer. In some such embodiments, a thinned portion of the conformally deposited dielectric layer is retained on sidewalls of the trench (e.g., on spacer layers adjacent gate structures). In some embodiments, the etching and exposing of the source and drain bodies removes some (e.g., slight) portions of the exposed source and drain bodies.

FIG. 5E shows exposed source and drain bodies 110 with larger openings 543 in and through dielectrics 142, 143 and into dielectric 141, down to exposed bodies 110 in a workpiece or IC device 100, in accordance with some embodiments, for example, following a performance of exposing operation 460. Conformal layer 144 is removed over bodies 110. Bodies 110 are exposed and available for contacting. In some embodiments, some of layers 144 remain (e.g., thinned) on sidewall spacers 122.

Returning to FIG. 4, methods 400 continue with forming metallization structures on the exposed source and drain bodies at operation 470. Forming the metallization structures may be by any suitable means and with any suitable materials, for example, those described of metallization structure 130 at FIG. 1A. In many embodiments, the metallization structure includes one or more metal layers deposited over the exposed source and drain bodies. In some such embodiments, at least one liner (e.g., conformal) layer is first deposited over one or more source or drain bodies, and a fill layer is deposited over the liner layer(s). In many embodiments, the metallization structure is coupled to the source or drain body or bodies an interface layer (e.g., of metallized semiconductor body). A deposited liner layer may alloy or otherwise bond or interface with an upper surface of the source or drain body, for example, a highly conductive contact or interface layer of, on, or over the semiconductor body.

FIG. 5F illustrates IC device 100 and transistor structures 101 having source or drain bodies 110 coupled with metallization structures 130 adjacent protective dielectric 142 in dielectric stacks 140, in accordance with some embodiments, for example, following a performance of forming operation 470. Metallization structures 130 are on and coupled with source or drain bodies 110, e.g., at layers 132 and exposed bodies 110 (e.g., where not coved by layers 144). Dielectric stacks 140 are between bodies 110 and between structures 130. Bodies 110 are between stacks 140, and structures 130 are between stacks 140.

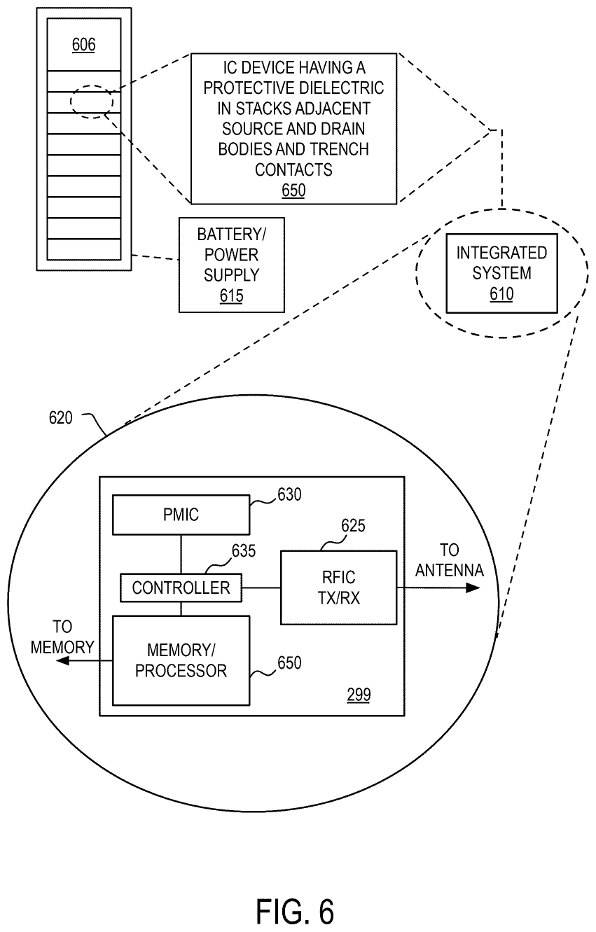

FIG. 6 illustrates a diagram of an example data server machine 606 employing an IC device having dielectric stacks with a protective dielectric adjacent source and drain bodies and trench contacts, in accordance with some embodiments. Server machine 606 may be any commercial server, for example, including any number of high-performance computing platforms disposed within a rack and networked together for electronic data processing, which in the exemplary embodiment includes one or more devices 650 having dielectric stacks with a protective dielectric adjacent source and drain bodies and trench contacts.

Also as shown, server machine 606 includes a battery and/or power supply 615 to provide power to devices 650, and to provide, in some embodiments, power delivery functions such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device having dielectric stacks with a protective dielectric adjacent source and drain bodies and trench contacts, as discussed herein. Device 650 may be further coupled to (e.g., communicatively coupled to) a board, an interposer, or a substrate (such as host component 299) along with, one or more of a power management IC (PMIC) 630, RF (wireless) IC (RFIC) 625 including a wideband RF (wireless) transmitter and/or receiver (TX/RX) (e.g., including a digital baseband and an analog front end module further includes a power amplifier on a transmit path and a low noise amplifier on a receive path), and a controller 635 thereof. In some embodiments, RFIC 625, PMIC 630, controller 635, and device 650 include having dielectric stacks with a protective dielectric adjacent source and drain bodies and trench contacts.

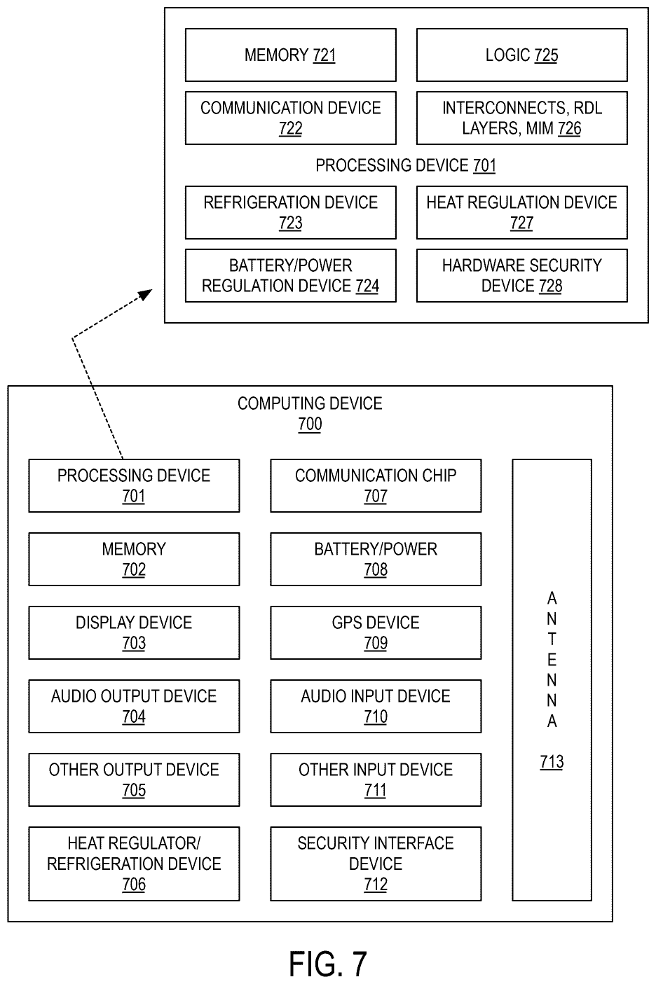

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) or spin transfer torque magnetic random-access memory (STT-MRAM).

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes adjacent first and second source or drain material bodies over a substrate, the first source or drain material body in a first transistor structure and the second source or drain material body in a second transistor structure, a first metallization structure on the first source or drain material body, a second metallization structure on the second source or drain material body, a first dielectric over the substrate in a stack, the first dielectric between the first and second source or drain material bodies and between the first and second metallization structures, a second dielectric between the first and second metallization structures, the second dielectric over the first dielectric in the stack, and a third dielectric between the first and second metallization structures, the third dielectric over the second dielectric in the stack.

In one or more second embodiments, further to the first embodiments, the stack is a first stack, the third dielectric is over the second dielectric, the second dielectric is over the first dielectric, and the first dielectric is over the substrate in second and third stacks, the first metallization structure is between the first and second stacks, and the second metallization structure is between the first and third stacks.

In one or more third embodiments, further to the first or second embodiments, a fourth dielectric is on a first sidewall of the first source or drain material body, the fourth dielectric is on a second sidewall of the second source or drain material body, and the first dielectric is between the fourth dielectric on the first and second sidewalls.

In one or more fourth embodiments, further to the first through third embodiments, a conformal layer including the fourth dielectric is on the first and second sidewalls, and the conformal layer is under the first dielectric between the first and second sidewalls.

In one or more fifth embodiments, further to the first through fourth embodiments, the apparatus also includes a third source or drain material body in a third transistor structure, wherein the first metallization structure is over and between the first and third source or drain material bodies, and a fourth source or drain material body in a fourth transistor structure, wherein the second metallization structure is over and between the second and fourth source or drain material bodies.

In one or more sixth embodiments, further to the first through fifth embodiments, a first intervening portion of the first metallization structure is between the first and third source or drain material bodies, a fourth dielectric is between the first intervening portion and the first source or drain material body and between the first intervening portion and the third source or drain material body, a second intervening portion of the second metallization structure is between the second and fourth source or drain material bodies, and the fourth dielectric is between the second intervening portion and the second source or drain material body and between the second intervening portion and the fourth source or drain material body.

In one or more seventh embodiments, further to the first through sixth embodiments, the stack is a first stack, the third dielectric is over the second dielectric, the second dielectric is over the first dielectric, and the first dielectric is over the substrate in second and third stacks, the first metallization structure is between the first and second stacks, and the second metallization structure is between the first and third stacks, and also including a third metallization structure on a third source or drain material body in a third transistor structure, wherein the second stack is between the first and third source or drain material bodies and between the first and third metallization structures, and a fourth metallization structure on a fourth source or drain material body in a fourth transistor structure, wherein the third stack is between the second and fourth source or drain material bodies and between the second and fourth metallization structures.

In one or more eighth embodiments, further to the first through seventh embodiments, the third dielectric is over the second dielectric, the second dielectric is over the first dielectric, and the first dielectric is over the substrate in fourth and fifth stacks, the third metallization structure is between the second and fourth stacks, and the fourth metallization structure is between the third and fifth stacks.

In one or more ninth embodiments, further to the first through eighth embodiments, a fourth dielectric is on a first sidewall of the first source or drain material body, the fourth dielectric is on a second sidewall of the second source or drain material body, the first dielectric in the first stack is between the fourth dielectric on the first and second sidewalls, the fourth dielectric is on a third sidewall of the first source or drain material body, the fourth dielectric is on a fourth sidewall of the third source or drain material body, the first dielectric in the second stack is between the fourth dielectric on the third and fourth sidewalls, the fourth dielectric is on a fifth sidewall of the second source or drain material body, the fourth dielectric is on a sixth sidewall of the fourth source or drain material body, and the first dielectric in the third stack is between the fourth dielectric on the fifth and sixth sidewalls.

In one or more tenth embodiments, further to the first through ninth embodiments, a first conformal layer including the fourth dielectric is on the first and second sidewalls, the first conformal layer is under the first dielectric in the first stack between the first and second sidewalls, a second conformal layer including the fourth dielectric is on the third and fourth sidewalls, the second conformal layer is under the first dielectric in the second stack between the third and fourth sidewalls, a third conformal layer including the fourth dielectric is on the fifth and sixth sidewalls, and the third conformal layer is under the first dielectric in the third stack between the fifth and sixth sidewalls.

In one or more eleventh embodiments, further to the first through tenth embodiments, the first and second dielectrics are in a trench extending in a first direction between the first and second source or drain material bodies, the third dielectric is over the trench, and the third dielectric extends beyond the trench in a second direction perpendicular to the first direction.

In one or more twelfth embodiments, further to the first through eleventh embodiments, the first transistor structure includes a third source or drain material body coupled to the first source or drain material body by a first channel region, the second transistor structure includes a fourth source or drain material body coupled to the second source or drain material body by a second channel region, a third metallization structure is on the third source or drain material body, a fourth metallization structure is on the fourth source or drain material body, the stack is a first stack, and a second stack is between the third and fourth metallization structures, the second stack including the first, second, and third dielectrics, the third dielectric over the second dielectric, the second dielectric over the first dielectric, and the first dielectric over the substrate.

In one or more thirteenth embodiments, further to the first through twelfth embodiments, the first and second source or drain material bodies are in a first trench, the third and fourth source or drain material bodies are in a second trench, and the third dielectric is continuous over and between the first and second trenches.

In one or more fourteenth embodiments, further to the first through thirteenth embodiments, the first and second channel regions include nanoribbons.

In one or more fifteenth embodiments, further to the first through fourteenth embodiments, a third transistor structure includes a third source or drain material body, a fourth transistor structure includes a fourth source or drain material body, the first and second source or drain material bodies are in a first trench, the third source or drain material body is adjacent the fourth source or drain material body in a second trench, a third metallization structure is on the third source or drain material body, a fourth metallization structure is on the fourth source or drain material body, the stack is a first stack, and a second stack is between the third and fourth metallization structures, the second stack comprising the first, second, and third dielectrics, the third dielectric over the second dielectric, the second dielectric over the first dielectric, and the first dielectric over the substrate.

In one or more sixteenth embodiments, further to the first through fifteenth embodiments, a trench isolation is between and parallel to the first and second trenches, the isolation including silicon and nitrogen.

In one or more seventeenth embodiments, further to the first through sixteenth embodiments, the trench isolation includes a fifth dielectric between the first and third source or drain material bodies, the fifth dielectric including silicon and nitrogen, and the first dielectric between the second and fourth source or drain material bodies.

In one or more eighteenth embodiments, further to the first through seventeenth embodiments, a first layer of the fifth dielectric is between the first dielectric and the second source or drain material body, and a second layer of the fifth dielectric is between the first dielectric and the fourth source or drain material body.

In one or more nineteenth embodiments, further to the first through eighteenth embodiments, a first nanoribbon contacts the trench isolation and the first source or drain material body a second nanoribbon contacts the trench isolation and the second source or drain material body, a third nanoribbon contacts the trench isolation and the third source or drain material body, and a fourth nanoribbon contacts the trench isolation and the fourth source or drain material body.

In one or more twentieth embodiments, further to the first through nineteenth embodiments, the substrate is coupled to a power supply on or through a host component.

In one or more twenty-first embodiments, further to the first through twentieth embodiments, the second dielectric includes aluminum and oxygen.

In one or more twenty-second embodiments, an apparatus includes adjacent first and second source or drain material bodies in a trench over a substrate, the first source or drain material body in a first transistor structure and the second source or drain material body in a second transistor structure, a first metallization structure on the first source or drain material body, a second metallization structure on the second source or drain material body, a first dielectric in the trench, the first dielectric between the first and second source or drain material bodies and between the first and second metallization structures, a second dielectric on the first dielectric, in the trench, and between the first and second metallization structures, and a third dielectric on the second dielectric and between the first and second metallization structures.

In one or more twenty-third embodiments, further to the twenty-second embodiments, a first layer of a fourth dielectric is on the first source or drain material body, a second layer of the fourth dielectric is on the second source or drain material body, and the first dielectric is on and between the first and second layers.

In one or more twenty-fourth embodiments, further to the twenty-second or twenty-third embodiments, the trench extends in a first direction between the first and second source or drain material bodies, the first and second dielectrics are in the trench, the third dielectric is over the trench, and the third dielectric extends beyond the trench in a second direction perpendicular to the first direction.

In one or more twenty-fifth embodiments, further to the twenty-second through twenty-fourth embodiments, the trench is a first trench, and also including a second trench extending in the first direction, the second trench including third and fourth source or drain material bodies, and a dielectric structure extending in the first direction, the dielectric structure between the first and second trenches, wherein a first stack of nanoribbons is in contact with the dielectric structure and the first source or drain material body, a second stack of nanoribbons is in contact with the dielectric structure and the second source or drain material body, a third stack of nanoribbons is in contact with the dielectric structure and the third source or drain material body, and a fourth stack of nanoribbons is in contact with the dielectric structure and the fourth source or drain material body.

In one or more twenty-sixth embodiments, a method includes depositing a first dielectric between first and second sidewalls over a substrate, over and between first and second semiconductor bodies on the substrate, depositing a second dielectric over the first dielectric between the first and second sidewalls, depositing a third dielectric layer over the second dielectric, exposing the first and second semiconductor bodies by etching through the third dielectric, and forming metallization structures on the exposed first and second semiconductor bodies.

In one or more twenty-seventh embodiments, further to the twenty-sixth embodiments, the method also includes conformally depositing a fourth dielectric layer over the first and second semiconductor bodies, wherein the depositing the first dielectric over and between the first and second semiconductor bodies is over and within the conformally deposited fourth dielectric layer.

In one or more twenty-eighth embodiments, further to the twenty-sixth or twenty-seventh embodiments, the depositing the first dielectric between the first and second sidewalls over the substrate, over and between the first and second semiconductor bodies also deposits the first dielectric between third and fourth sidewalls over the substrate and over and between third and fourth semiconductor bodies, wherein the first and second sidewalls extend in a direction over the substrate, the third and fourth sidewalls extend in the direction over the substrate, and the third and fourth semiconductor bodies are on the substrate, and also including forming an opening by etching to the substrate between the second and third sidewalls, depositing the first dielectric in the opening between the second and third sidewalls, removing a first portion of the first dielectric between the first and third semiconductor bodies, between the second and third sidewalls, and depositing a fourth dielectric between the second and third sidewalls.

In one or more twenty-ninth embodiments, further to the twenty-sixth through twenty-eighth embodiments, the method also includes conformally depositing the fourth dielectric over the opening, wherein the depositing the first dielectric between the second and third sidewalls includes depositing the first dielectric in and between the conformally deposited fourth dielectric.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
first and second source or drain material bodies over a substrate, the first source or drain material body in a first transistor structure and the second source or drain material body in a second transistor structure;
a first metallization structure on the first source or drain material body;
a second metallization structure on the second source or drain material body;
a first dielectric over the substrate in a stack, the first dielectric between the first and second source or drain material bodies and between the first and second metallization structures;
a second dielectric between the first and second metallization structures, the second dielectric over the first dielectric in the stack; and
a third dielectric between the first and second metallization structures, the third dielectric over the second dielectric in the stack.

2. The apparatus of claim 1, wherein:
the stack is a first stack;
the third dielectric is over the second dielectric, the second dielectric is over the first dielectric, and the first dielectric is over the substrate in second and third stacks;
the first metallization structure is between the first and second stacks; and
the second metallization structure is between the first and third stacks.

3. The apparatus of claim 1, wherein:
a fourth dielectric is on a first sidewall of the first source or drain material body;
the fourth dielectric is on a second sidewall of the second source or drain material body; and
the first dielectric is between the fourth dielectric on the first and second sidewalls.

4. The apparatus of claim 3, wherein a conformal layer comprising the fourth dielectric is on the first and second sidewalls, and the conformal layer is under the first dielectric between the first and second sidewalls.

5. The apparatus of claim 1, further comprising:
a third source or drain material body in a third transistor structure, wherein the first metallization structure is over and between the first and third source or drain material bodies; and
a fourth source or drain material body in a fourth transistor structure, wherein the second metallization structure is over and between the second and fourth source or drain material bodies.

6. The apparatus of claim 5, wherein:
a first intervening portion of the first metallization structure is between the first and third source or drain material bodies;
a fourth dielectric is between the first intervening portion and the first source or drain material body and between the first intervening portion and the third source or drain material body;
a second intervening portion of the second metallization structure is between the second and fourth source or drain material bodies; and
the fourth dielectric is between the second intervening portion and the second source or drain material body and between the second intervening portion and the fourth source or drain material body.

7. The apparatus of claim 1, wherein:
the stack is a first stack;
the third dielectric is over the second dielectric, the second dielectric is over the first dielectric, and the first dielectric is over the substrate in second and third stacks;
the first metallization structure is between the first and second stacks; and
the second metallization structure is between the first and third stacks, and further comprising:
a third metallization structure on a third source or drain material body in a third transistor structure, wherein the second stack is between the first and third source or drain material bodies and between the first and third metallization structures; and
a fourth metallization structure on a fourth source or drain material body in a fourth transistor structure, wherein the third stack is between the second and fourth source or drain material bodies and between the second and fourth metallization structures.

8. The apparatus of claim 7, wherein:
the third dielectric is over the second dielectric, the second dielectric is over the first dielectric, and the first dielectric is over the substrate in fourth and fifth stacks;
the third metallization structure is between the second and fourth stacks; and
the fourth metallization structure is between the third and fifth stacks.

9. The apparatus of claim 7, wherein:
a fourth dielectric is on a first sidewall of the first source or drain material body;
the fourth dielectric is on a second sidewall of the second source or drain material body;
the first dielectric in the first stack is between the fourth dielectric on the first and second sidewalls;
the fourth dielectric is on a third sidewall of the first source or drain material body;
the fourth dielectric is on a fourth sidewall of the third source or drain material body;
the first dielectric in the second stack is between the fourth dielectric on the third and fourth sidewalls;
the fourth dielectric is on a fifth sidewall of the second source or drain material body;
the fourth dielectric is on a sixth sidewall of the fourth source or drain material body; and
the first dielectric in the third stack is between the fourth dielectric on the fifth and sixth sidewalls.

10. The apparatus of claim 9, wherein:
a first conformal layer comprising the fourth dielectric is on the first and second sidewalls;
the first conformal layer is under the first dielectric in the first stack between the first and second sidewalls;
a second conformal layer comprising the fourth dielectric is on the third and fourth sidewalls;
the second conformal layer is under the first dielectric in the second stack between the third and fourth sidewalls;
a third conformal layer comprising the fourth dielectric is on the fifth and sixth sidewalls; and
the third conformal layer is under the first dielectric in the third stack between the fifth and sixth sidewalls.

11. The apparatus of claim 1, wherein the first and second dielectrics are in a trench extending in a first direction between the first and second source or drain material bodies, the third dielectric is over the trench, and the third dielectric extends beyond the trench in a second direction perpendicular to the first direction.

12. The apparatus of claim 1, wherein the second dielectric comprises aluminum and oxygen.

13. An apparatus, comprising:
first and second source or drain material bodies in a trench over a substrate, the first source or drain material body in a first transistor structure and the second source or drain material body in a second transistor structure;
a first metallization structure on the first source or drain material body;
a second metallization structure on the second source or drain material body;
a first dielectric in the trench, the first dielectric between the first and second source or drain material bodies and between the first and second metallization structures;
a second dielectric on the first dielectric, in the trench, and between the first and second metallization structures; and
a third dielectric on the second dielectric and between the first and second metallization structures.

14. The apparatus of claim 13, wherein:
a first layer of a fourth dielectric is on the first source or drain material body;
a second layer of the fourth dielectric is on the second source or drain material body; and
the first dielectric is on and between the first and second layers.

15. The apparatus of claim 14, wherein the trench extends in a first direction between the first and second source or drain material bodies, the first and second dielectrics are in the trench, the third dielectric is over the trench, and the third dielectric extends beyond the trench in a second direction perpendicular to the first direction.

16. The apparatus of claim 15, wherein the trench is a first trench, and further comprising:
a second trench extending in the first direction, the second trench comprising third and fourth source or drain material bodies; and
a dielectric structure extending in the first direction, the dielectric structure between the first and second trenches, wherein:
a first stack of nanoribbons is in contact with the dielectric structure and the first source or drain material body;
a second stack of nanoribbons is in contact with the dielectric structure and the second source or drain material body;
a third stack of nanoribbons is in contact with the dielectric structure and the third source or drain material body; and
a fourth stack of nanoribbons is in contact with the dielectric structure and the fourth source or drain material body.

17. A method, comprising:
depositing a first dielectric between first and second sidewalls over a substrate, over and between first and second semiconductor bodies on the substrate;
depositing a second dielectric over the first dielectric between the first and second sidewalls;
depositing a third dielectric layer over the second dielectric;
exposing the first and second semiconductor bodies by etching through the third dielectric; and
forming metallization structures on the exposed first and second semiconductor bodies.

18. The method of claim 17, further comprising conformally depositing a fourth dielectric layer over the first and second semiconductor bodies, wherein the depositing the first dielectric over and between the first and second semiconductor bodies is over and within the conformally deposited fourth dielectric layer.

19. The method of claim 17, wherein the depositing the first dielectric between the first and second sidewalls over the substrate, over and between the first and second semiconductor bodies also deposits the first dielectric between third and fourth sidewalls over the substrate and over and between third and fourth semiconductor bodies, wherein the first and second sidewalls extend in a direction over the substrate, the third and fourth sidewalls extend in the direction over the substrate, and the third and fourth semiconductor bodies are on the substrate, and further comprising:
forming an opening by etching to the substrate between the second and third sidewalls;
depositing the first dielectric in the opening between the second and third sidewalls;
removing a first portion of the first dielectric between the first and third semiconductor bodies, between the second and third sidewalls; and
depositing a fourth dielectric between the second and third sidewalls.

20. The method of claim 19, further comprising conformally depositing the fourth dielectric over the opening, wherein the depositing the first dielectric between the second and third sidewalls comprises depositing the first dielectric in and between the conformally deposited fourth dielectric.
